(19) United States
(12) Patent Application Publication
(10) Pub. No.: US 2017/0062192 A1
(43) Pub. Date: Mar. 2, 2017

(54) FILM FORMING APPARATUS

(71) Applicant: Semiconductor Energy Laboratory Co., Ltd., Atsugi-shi (JP)

(72) Inventors: Masashi OOTA, Atsugi (JP); Takuya KAWATA, Atsugi (JP); Yasumasa YAMANE, Atsugi (JP); Yuta ENDO, Atsugi (JP)

(73) Assignee: Semiconductor Energy Laboratory Co., Ltd.

(21) Appl. No.: 15/234,347

(22) Filed: Aug. 11, 2016

(30) Foreign Application Priority Data
Aug. 28, 2015 (JP) 2015-168607
Aug. 28, 2015 (JP) 2015-168610

(51) Int. Cl. H01J 37/34; C23C 14/35; H01L 29/786; H01L 29/66; H01L 21/02

(52) U.S. Cl. CPC H01J 37/3405; H01L 29/66969; H01L 21/02565; H01L 29/7869; C23C 14/35; H01J 37/3435; H01J 37/3452

(57) ABSTRACT

An oxide with high crystallinity is provided. An oxide having a crystal structure with few defects is provided. An oxide with a low density of defect states is provided. An oxide with a low impurity concentration is provided. A film forming apparatus capable of forming a film of the above-described oxide can be provided. The film forming apparatus includes a target holder, a substrate holder, a first power source, and a second power source. The target holder is electrically connected to the first power source, the substrate holder is electrically connected to the second power source, and the second power source is configured to apply a potential that is higher than a ground potential.

### BACKGROUND OF THE INVENTION

1. Field of the Invention

One embodiment of the present invention relates to a film forming apparatus.

The present invention relates to, for example, an oxide, a transistor, a semiconductor device, and manufacturing methods thereof. The present invention relates to, for example, an oxide, a display device, a light-emitting device, a lighting device, a power storage device, a memory device, an imaging device, a processor, or an electronic device. The present invention relates to a method for forming an oxide, a display device, a liquid crystal display device, a light-emitting device, a memory device, and an electronic device. The present invention relates to a driving method of a semiconductor device, a display device, a liquid crystal display device, a light-emitting device, a memory device, and an electronic device.

Note that one embodiment of the present invention is not limited to the above technical field. The technical field of one embodiment of the invention disclosed in this specification and the like relates to an object, a method, and a manufacturing method. In addition, one embodiment of the present invention relates to a process, a machine, manufacture, or a composition of matter.

In this specification and the like, a semiconductor device generally means a device that can function by utilizing semiconductor characteristics. A display device, a light-emitting device, a lighting device, an imaging device, an electro-optical device, a semiconductor circuit, and an electronic device include a semiconductor device in some cases.

2. Description of the Related Art

A technique for forming a transistor by using a semiconductor over a substrate having an insulating surface has attracted attention. Such a transistor is used in a wide range of semiconductor devices such as an integrated circuit and a display device. Silicon is known as a semiconductor that can be used in a transistor.

As silicon which is used as a semiconductor of a transistor, either amorphous silicon or polycrystalline silicon is used depending on the purpose. For example, in the case of a transistor included in a large display device, it is preferable to use amorphous silicon, which can be used to form a film on a large substrate with the established technique. On the other hand, in the case of a transistor included in a high-performance display device where a driver circuit and a pixel circuit are formed over the same substrate, it is preferable to use polycrystalline silicon, which can be used to form a transistor having a high field-effect mobility. As a method for forming polycrystalline silicon, high-temperature heat treatment or laser light treatment which is performed on amorphous silicon has been known.

In recent years, transistors using oxide semiconductors (typically, In—Ga—Zn oxide) have been actively developed.

Oxide semiconductors have been researched since early times. In 1988, there was a disclosure of a crystal In—Ga—Zn oxide that can be used for a semiconductor element (see Patent Document 1). In 1995, a transistor using an oxide semiconductor was invented, and its electrical characteristics were disclosed (see Patent Document 2).

In 2013, one group reported that an amorphous In—Ga—Zn oxide had such an unstable structure that crystallization was induced by irradiation with an electron beam (see Non-Patent Document 1). According to the report, no ordering was observed with a high-resolution transmission electron microscope in the amorphous In—Ga—Zn oxide formed by the group.

In 2014, a transistor using a crystalline In—Ga—Zn oxide that has more excellent electrical characteristics and higher reliability than a transistor using an amorphous In—Ga—Zn oxide was reported (see Non-Patent Document 2). These documents reported that a grain boundary was not clearly observed in an In—Ga—Zn oxide including a c-axis-aligned crystalline oxide semiconductor (CAAC-OS).

### REFERENCE

### Patent Document

[Patent Document 1] Japanese Published Patent Application No. S63-239117
[Patent Document 2] Japanese Translation of PCT International Application No. H11-505377

### Non-Patent Document

[Non-Patent Document 1] T. Kamiya, Koji Kimoto, Naoki Ohashi, Katsumi Abe, Yuichiro Hanyu, Hideya Kumomi, and Hideo Hosono, Proceedings of The 20th International Display Workshops, 2013, AMD2-5L
[Non-Patent Document 2] S. Yamazaki, The Electrochemical Society Transactions, Vol. 64(10), 2014, pp. 155-164

### SUMMARY OF THE INVENTION

An object is to provide an oxide with high crystallinity. Another object is to provide an oxide having a crystal structure with few defects. Another object is to provide an oxide with a low density of defect states. Another object is to provide an oxide having a novel crystal structure. Another object is to provide an oxide with a low impurity concentration. Another object is to provide a film forming apparatus capable of forming a film of the above-described oxide.

Another object is to provide a semiconductor device using an oxide as a semiconductor. Another object is to provide a module that includes a semiconductor device using an oxide as a semiconductor. Another object is to provide an electronic device that includes a semiconductor device using an oxide as a semiconductor, or an electronic device that includes a module including a semiconductor device using an oxide as a semiconductor.

Another object is to provide a transistor with favorable electrical characteristics. Another object is to provide a transistor having stable electrical characteristics. Another object is to provide a transistor with high frequency characteristics. Another object is to provide a transistor having a low off-state current. Another object is to provide a semiconductor device including the above-described transistor. Another object is to provide a module including the above-described semiconductor device. Another object is to provide an electronic device including the above-described semiconductor device or the above-described module.

Note that the descriptions of these objects do not disturb the existence of other objects. In one embodiment of the present invention, there is no need to achieve all of these objects. Other objects will be apparent from and can be derived from the description of the specification, the drawings, the claims, and the like.

One embodiment of the present invention is a film forming apparatus including a target holder, a substrate holder, a first power source, and a second power source. In the film forming apparatus, the target holder is electrically connected to the first power source, the substrate holder is electrically connected to the second power source, and the second power source is configured to apply a potential that is higher than a ground potential.

One embodiment of the present invention is the film forming apparatus described above, in which the second power source is configured to apply a potential that is higher than a potential of plasma generated during film formation.

One embodiment of the present invention is a film forming apparatus including a target holder, a substrate holder, a first inlet, and a second inlet. In the film forming apparatus, the first inlet is positioned closer to the target holder than to the substrate holder, the second inlet is positioned closer to the substrate holder than to the target holder, the first inlet is configured to introduce a first gas, and the second inlet is configured to introduce a second gas.

One embodiment of the present invention is the film forming apparatus described above, in which, during film formation, a concentration of the first gas near the target holder is high and a concentration of the second gas near the substrate holder is high.

One embodiment of the present invention is the film forming apparatus described above, in which a maximum magnetic flux density in a direction perpendicular to a front surface of the target holder is more than or equal to 50 G and less than or equal to 150 G at a plane that is 30 mm away in the perpendicular direction from the front surface of the target holder.

One embodiment of the present invention is a film forming apparatus including a first target holder, a second target holder, a substrate holder, a first power source, and a second power source. In the film forming apparatus, the first target holder and the second target holder are electrically connected to the first power source, the substrate holder is electrically connected to the second power source, and the second power source is configured to apply a potential that is higher than a ground potential.

One embodiment of the present invention is the film forming apparatus described above, in which the second power source is configured to apply a potential that is higher than a potential of plasma generated during film formation.

One embodiment of the present invention is a film forming apparatus including a first target holder, a second target holder, a substrate holder, a first inlet, and a second inlet. In the film forming apparatus, the first inlet is positioned closer to the first target holder and the second target holder than to the substrate holder, the second inlet is positioned closer to the substrate holder than to the first target holder and the second target holder, the first inlet is configured to introduce a first gas, and the second inlet is configured to introduce a second gas.

One embodiment of the present invention is the film forming apparatus described above, in which, during film formation, a concentration of the first gas near the first target holder and the second target holder is high and a concentration of the second gas near the substrate holder is high.

One embodiment of the present invention is the film forming apparatus described above, in which a maximum magnetic flux density in a direction perpendicular to a front surface of the first target holder is more than or equal to 50 G and less than or equal to 150 G at a plane that is 30 mm away in the perpendicular direction from the front surface of the first target holder.

One embodiment of the present invention is the film forming apparatus described above, in which a maximum magnetic flux density in a direction perpendicular to a front surface of the second target holder is more than or equal to 50 G and less than or equal to 150 G at a plane that is 30 mm away in the perpendicular direction from the front surface of the second target holder.

An oxide with high crystallinity can be provided. An oxide having a crystal structure with few defects can be provided. An oxide with a low density of defect states can be provided. An oxide having a novel crystal structure can be provided. An oxide with a low impurity concentration can be provided. A film forming apparatus capable of forming a film of the above-described oxide can be provided.

A semiconductor device using an oxide as a semiconductor can be provided. A module including a semiconductor device using an oxide as a semiconductor can be provided. An electronic device that includes a semiconductor device using an oxide as a semiconductor, or an electronic device that includes a module including a semiconductor device using an oxide as a semiconductor can be provided.

A transistor with favorable electrical characteristics can be provided. A transistor having stable electrical characteristics can be provided. A transistor with high frequency characteristics can be provided. A transistor having a low off-state current can be provided. A semiconductor device including the above-described transistor can be provided. A module including the above-described semiconductor device can be provided. An electronic device including the above-described semiconductor device or the above-described module can be provided.

Note that the descriptions of these effects do not disturb the existence of other effects. One embodiment of the present invention does not necessarily have all of these effects. Other effects will be apparent from and can be derived from the description of the specification, the drawings, the claims, and the like.

### BRIEF DESCRIPTION OF THE DRAWINGS

In the accompanying drawings:

FIG. 1 is a top view illustrating an example of a film forming apparatus;

FIGS. 2A to 2C are cross-sectional views illustrating an example of a film forming apparatus;

FIGS. 3A to 3C are cross-sectional views illustrating an example of a film forming apparatus;

FIG. 4 illustrates a sputtering apparatus;

FIG. 5 illustrates a sputtering apparatus;

FIG. 6 illustrates a sputtering apparatus;

FIG. 7 illustrates a sputtering apparatus;

FIG. 8 is a triangular diagram for explaining composition of an In-M-Zn oxide;

FIGS. 9A to 9E show structural analysis results of a CAAC-OS and a single crystal oxide semiconductor by XRD and selected-area electron diffraction patterns of a CAAC-OS;

FIGS. 10A to 10E show a cross-sectional TEM image and plan-view TEM images of a CAAC-OS and images obtained through analysis thereof;

FIGS. 11A to 11D show electron diffraction patterns and a cross-sectional TEM image of an nc-OS;

FIGS. 12A and 12B show cross-sectional TEM images of an a-like OS;

FIG. 13 shows a change in crystal part of an In—Ga—Zn oxide induced by electron irradiation;

FIGS. 14A to 14C are a top view and cross-sectional views illustrating a transistor of one embodiment of the present invention;

FIGS. 15A to 15F are cross-sectional views each illustrating a transistor of one embodiment of the present invention;

FIGS. 16A to 16F are cross-sectional views each illustrating a transistor of one embodiment of the present invention;

FIG. 17 is a band diagram of a region including an oxide semiconductor according to one embodiment of the present invention;

FIGS. 18A to 18C are a top view and cross-sectional views illustrating a transistor of one embodiment of the present invention;

FIGS. 19A to 19F are cross-sectional views each illustrating a transistor of one embodiment of the present invention;

FIGS. 20A to 20F are cross-sectional views each illustrating a transistor of one embodiment of the present invention;

FIGS. 21A to 21C are a top view and cross-sectional views illustrating a transistor of one embodiment of the present invention; and

FIGS. 22A to 22F are cross-sectional views each illustrating a transistor of one embodiment of the present invention.

### DETAILED DESCRIPTION OF THE INVENTION

Hereinafter, embodiments of the present invention will be described in detail with the reference to the drawings. However, the present invention is not limited to the description below, and it is easily understood by those skilled in the art that modes and details disclosed herein can be modified in various ways. Furthermore, the present invention is not construed as being limited to description of the embodiments. In describing structures of the invention with reference to the drawings, common reference numerals are used for the same portions in different drawings. Note that the same hatched pattern is applied to similar parts, and the similar parts are not denoted by reference numerals in some cases. In the case where the description of a component denoted by a different reference numeral is referred to, the description of the thickness, composition, structure, shape, or the like of the component can be used as appropriate.

Note that the size, the thickness of films (layers), or regions in drawings is sometimes exaggerated for simplicity.

In this specification, the terms “film” and “layer” can be interchanged with each other.

A voltage usually refers to a potential difference between a given potential and a reference potential (e.g., a source potential or a ground potential (GND)). A voltage can be referred to as a potential. Note that in general, a potential (a voltage) is relative and is determined depending on the amount relative to a reference potential. Therefore, a potential that is represented as a “ground potential” or the like is not always 0 V. For example, the lowest potential in a circuit may be represented as a “ground potential.” Alternatively, a substantially intermediate potential in a circuit may be represented as a “ground potential.” In these cases, a positive potential and a negative potential are set using the potential as a reference.

Note that the ordinal numbers such as “first” and “second” are used for convenience and do not denote the order of steps or the stacking order of layers. Therefore, for example, the term “first” can be replaced with the term “second,” “third,” or the like as appropriate. In addition, the ordinal numbers in this specification and the like do not correspond to the ordinal numbers which specify one embodiment of the present invention in some cases.

Note that impurities in a semiconductor refer to, for example, elements other than the main components of the semiconductor. For example, an element with a concentration of lower than 0.1 atomic % is an impurity. When an impurity is contained, the density of states (DOS) may be formed in a semiconductor, the carrier mobility may be decreased, or the crystallinity may be decreased. In the case where the semiconductor is an oxide semiconductor, examples of an impurity which changes characteristics of the semiconductor include Group 1 elements, Group 2 elements, Group 13 elements, Group 14 elements, Group 15 elements, and transition metals other than the main components; specifically, there are hydrogen (included in water), lithium, sodium, silicon, boron, phosphorus, carbon, and nitrogen, for example. In the case of an oxide semiconductor, oxygen vacancies may be formed by entry of impurities such as hydrogen. In the case where the semiconductor is silicon, examples of an impurity which changes characteristics of the semiconductor include oxygen, Group 1 elements except hydrogen, Group 2 elements, Group 13 elements, and Group 15 elements. Note that as well as the impurity, a main component element that is excessively contained might cause DOS. In that case, DOS can be lowered in some cases by a slight amount of an additive (e.g., greater than or equal to 0.001 atomic % and less than 3 atomic %). The above-described element that might serve as an impurity can be used as the additive.

Note that the channel length refers to, for example, the distance between a source (a source region or a source electrode) and a drain (a drain region or a drain electrode) in a region where a semiconductor (or a portion where a current flows in a semiconductor when a transistor is on) and a gate electrode overlap with each other or a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

The channel width refers to, for example, the length of a portion where a source and a drain face each other in a region where a semiconductor (or a portion where a current flows in a semiconductor when a transistor is on) and a gate electrode overlap with each other, or a region where a channel is formed. In one transistor, channel widths in all regions are not necessarily the same. In other words, the channel width of one transistor is not limited to one value in some cases. Therefore, in this specification, the channel width is any one of values, the maximum value, the minimum value, or the average value in a region where a channel is formed.

Note that depending on a transistor structure, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is high in some cases. In that case, an effective channel width obtained when a channel is actually formed is greater than an apparent channel width shown in the top view.

In a transistor having a three-dimensional structure, an effective channel width is difficult to measure in some cases. For example, to estimate an effective channel width from a design value, it is necessary to assume that the shape of a semiconductor is known. Therefore, in the case where the shape of a semiconductor is not known accurately, it is difficult to measure an effective channel width accurately.

Therefore, in this specification, in a top view of a transistor, an apparent channel width that is a length of a portion where a source and a drain face each other in a region where a semiconductor and a gate electrode overlap with each other is referred to as a surrounded channel width (SCW) in some cases. Furthermore, in this specification, in the case where the term “channel width” is simply used, it may denote a surrounded channel width or an apparent channel width. Alternatively, in this specification, in the case where the term “channel width” is simply used, it may denote an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where field-effect mobility, a current value per channel width, and the like of a transistor are obtained by calculation, a surrounded channel width may be used for the calculation. In that case, the values might be different from those calculated by using an effective channel width.

In this specification, the expression “A has a shape such that an end portion extends beyond an end portion of B” may indicate the case where at least one end portion of A is positioned on an outer side than at least one end portion of B in a top view or a cross-sectional view. Therefore, the expression “A has a shape such that an end portion extends beyond an end portion of B” can also be expressed as “an end portion of A is positioned on an outer side than an end portion of B in a top view,” for example.

In this specification, the term “parallel” indicates that the angle formed between two straight lines is greater than or equal to −10° and less than or equal to 10°, and accordingly also includes the case where the angle is greater than or equal to −5° and less than or equal to 5°. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly also includes the case where the angle is greater than or equal to 85° and less than or equal to 95°. The term “substantially perpendicular” indicates that the angle formed between two straight lines is greater than or equal to 60° and less than or equal to 120°.

In this specification, trigonal and rhombohedral crystal systems are included in a hexagonal crystal system.

### <Film Forming Apparatus 1>

A film forming apparatus of one embodiment of the present invention will be described below.

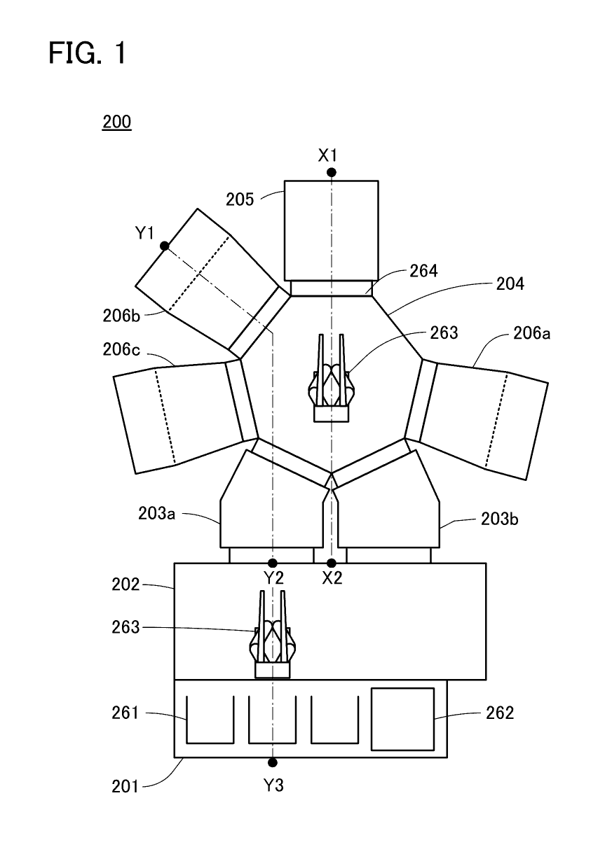

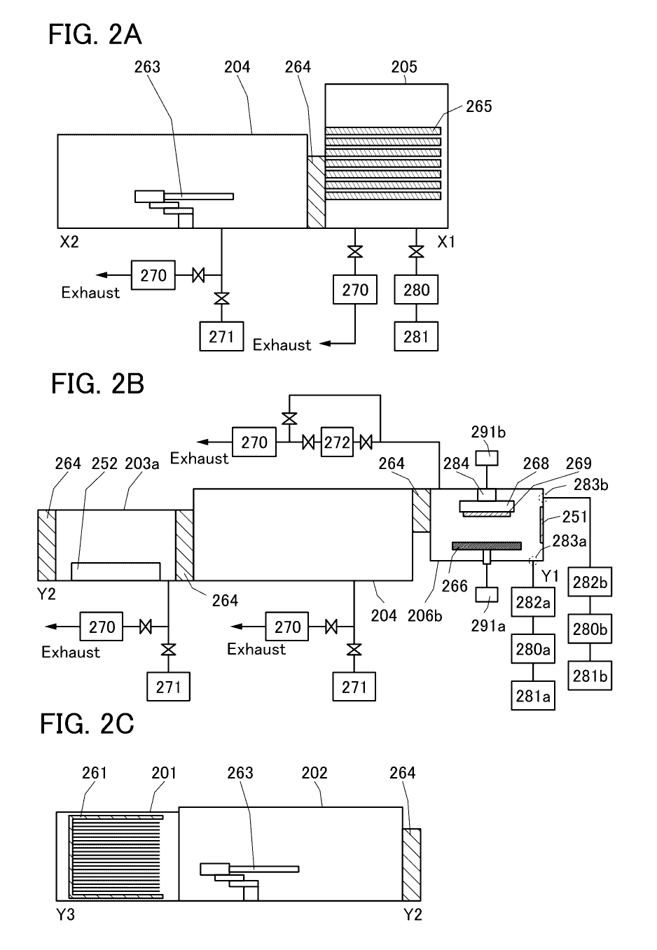

First, a structure of a film forming apparatus which allows the entry of few impurities into a film during film formation or the like and allows film formation of a highly crystalline oxide is described with reference to FIG. 1 and FIGS. 2A to 2C.

FIG. 1 is a top view schematically illustrating a single wafer multi-chamber film forming apparatus 200. The film forming apparatus 200 includes an atmosphere-side substrate supply chamber 201 including a cassette port 261 for holding a substrate and an alignment port 262 for performing alignment of a substrate, an atmosphere-side substrate transfer chamber 202 through which a substrate is transferred from the atmosphere-side substrate supply chamber 201, a load lock chamber 203a through which a substrate is carried in and the pressure inside the chamber is switched from atmospheric pressure to reduced pressure or from reduced pressure to atmospheric pressure, an unload lock chamber 203b through which a substrate is carried out and the pressure inside the chamber is switched from reduced pressure to atmospheric pressure or from atmospheric pressure to reduced pressure, a transfer chamber 204 through which a substrate is transferred in a vacuum, a substrate heating chamber 205 where a substrate is heated, and film forming chambers 206a, 206b, and 206c in each of which a target is placed for film-formation.

The atmosphere-side substrate transfer chamber 202 is connected to the load lock chamber 203a and the unload lock chamber 203b, the load lock chamber 203a and the unload lock chamber 203b are connected to the transfer chamber 204, and the transfer chamber 204 is connected to the substrate heating chamber 205 and the film forming chambers 206a, 206b, and 206c.

Gate valves 264 are provided at connecting portions between chambers so that each chamber except the atmosphere-side substrate supply chamber 201 and the atmosphere-side substrate transfer chamber 202 can be independently kept under vacuum. Moreover, the atmosphere-side substrate transfer chamber 202 and the transfer chamber 204 each include a transfer robot 263, with which a substrate can be transferred.

Furthermore, it is preferable that the substrate heating chamber 205 also serve as a plasma treatment chamber. In the film forming apparatus 200, it is possible to transfer a substrate without exposure to the air between treatments; therefore, adsorption of impurities on a substrate can be suppressed. In addition, the order of film formation, heat treatment, or the like can be freely determined. Note that the number of transfer chambers, the number of film forming chambers, the number of load lock chambers, the number of unload lock chambers, and the number of substrate heating chambers are not limited to the above-described numbers, and the numbers thereof can be determined as appropriate depending on the space for placement or the process conditions.

Next, FIG. 2A, FIG. 2B, and FIG. 2C are a cross-sectional view taken along dashed-dotted line X1-X2, a cross-sectional view taken along dashed-dotted line Y1-Y2, and a cross-sectional view taken along dashed-dotted line Y2-Y3, respectively, in the film forming apparatus 200 illustrated in FIG. 1.

FIG. 2A shows a cross section of the substrate heating chamber 205 and the transfer chamber 204, and the substrate heating chamber 205 includes a plurality of heating stages 265 which can hold substrates. Furthermore, the substrate heating chamber 205 is connected to a vacuum pump 270 through a valve. As the vacuum pump 270, a dry pump and a mechanical booster pump can be used, for example.

As heating mechanism which can be used for the substrate heating chamber 205, a resistance heater may be used for heating, for example. Alternatively, heat conduction or heat radiation from a medium such as a heated gas may be used as the heating mechanism. For example, rapid thermal annealing (RTA) such as gas rapid thermal annealing (GRTA) or lamp rapid thermal annealing (LRTA) can be used. The LRTA is a method for heating an object by radiation of light (an electromagnetic wave) emitted from a lamp such as a halogen lamp, a metal halide lamp, a xenon arc lamp, a carbon arc lamp, a high-pressure sodium lamp, or a high-pressure mercury lamp. In the GRTA, heat treatment is performed using a high-temperature gas. An inert gas is used as the gas.

Moreover, the substrate heating chamber 205 is connected to a refiner 281 through a mass flow controller 280. Note that although the mass flow controller 280 and the refiner 281 are provided for each kind of gas, only one mass flow controller 280 and one refiner 281 are provided for easy understanding. As the gas introduced to the substrate heating chamber 205, a gas whose dew point is −80° C. or lower, preferably −100° C. or lower, can be used; for example, an oxygen gas, a nitrogen gas, and a rare gas (e.g., argon) are used.

The transfer chamber 204 includes the transfer robot 263. The transfer robot 263 can transfer a substrate to each chamber. Furthermore, the transfer chamber 204 is connected to another vacuum pump 270 and a cryopump 271 through valves. Owing to such a structure, exhaust is performed inside the transfer chamber 204 using the vacuum pump 270 from the atmospheric pressure to low or medium vacuum (approximately 0.1 Pa to several hundred pascals) and then the valves are switched and exhaust is performed using the cryopump 271 from the medium vacuum to high or ultra-high vacuum (0.1 Pa to 1×10⁻⁷ Pa).

Furthermore, for example, two or more cryopumps 271 may be connected in parallel to the transfer chamber 204. With such a structure, even when one of the cryopumps is in regeneration, exhaust can be performed using any of the other cryopumps. Note that “regeneration” refers to treatment for discharging molecules (or atoms) entrapped in the cryopump. When molecules (or atoms) are entrapped too much in a cryopump, the exhaust capability of the cryopump is lowered; therefore, regeneration is performed regularly.

FIG. 2B shows a cross section of the film forming chamber 206b, the transfer chamber 204, and the load lock chamber 203a.

Here, the details of the film forming chamber (film forming chamber including a sputtering apparatus) are described with reference to FIG. 2B. A structure of the film forming chamber 206b is described below. The film forming chambers 206a and 206c can have the same structure as the film forming chamber 206b. The film forming chamber 206b illustrated in FIG. 2B includes a target holder 266, a substrate holder 268, and power sources 291a and 291b. The power source 291a is electrically connected to the target holder 266. A substrate 269 is supported by the substrate holder 268. The substrate holder 268 is fixed to the film forming chamber 206b by a member 284. Owing to the member 284, the distance between the target holder 266 and the substrate holder 268 can be changed. The power source 291b is electrically connected to the substrate holder 268. In this case, the substrate holder 268 and the film forming chamber 206b are preferably electrically separated from each other by an insulator or the like. Note that in some cases, the substrate holder 268 may be electrically connected to the film forming chamber 206b. Although not illustrated, the substrate holder 268 may include a substrate holding mechanism which holds the substrate 269, a heater which heats the substrate 269 from the back side, or the like.

A first inlet 283a of the film forming chamber 206b is connected to a mass flow controller 280a through a gas heating system 282a, and the gas heating system 282a is connected to a refiner 281a through the mass flow controller 280a. With the gas heating system 282a, a gas which is introduced to the film forming chamber 206b can be heated to a temperature higher than or equal to 40° C. and lower than or equal to 400° C. Note that although the gas heating system 282a, the mass flow controller 280a, and the refiner 281a are provided for each kind of gas, only one gas heating system 282a, one mass flow controller 280a, and one refiner 281a are illustrated for easy understanding. A second inlet 283b of the film forming chamber 206b is connected to a mass flow controller 280b through a gas heating system 282b, and the gas heating system 282b is connected to a refiner 281b through the mass flow controller 280b. With the gas heating system 282b, a gas which is introduced to the film forming chamber 206b can be heated to a temperature higher than or equal to 40° C. and lower than or equal to 400° C. Note that although the gas heating system 282b, the mass flow controller 280b, and the refiner 281b are provided for each kind of gas, only one gas heating system 282b, one mass flow controller 280b, and one refiner 281b are illustrated for easy understanding. As the gas introduced to the film forming chamber 206b, a gas whose dew point is −80° C. or lower, preferably −100° C. or lower, can be used; for example, an oxygen gas, a nitrogen gas, and a rare gas (e.g., argon) are used.

In the film forming chamber 206b, the first inlet 283a and the second inlet 283b are preferably disposed separate from each other. For example, the first inlet 283a is disposed at a position that is closer to the target holder 266 than to the substrate holder 268 and the second inlet 283b is disposed at a position that is closer to the substrate holder 268 than to the target holder 266. By this disposition, an introduced gas has a concentration gradient between the target holder 266 and the substrate holder 268. Specifically, by introducing an oxygen gas from the first inlet 283a and introducing argon from the second inlet 283b, a concentration gradient in which the proportion of oxygen increases (the proportion of argon decreases) from the substrate holder 268 toward the target holder 266 can be made. By this concentration gradient, stable plasma generation is possible in some cases while oxidation reaction is promoted in the vicinity of the target surface during film formation. Furthermore, it is preferable in some cases that the gas introduced from the first inlet 283a and/or the second inlet 283b be heated. For example, by heating the gas introduced from the first inlet 283a, a chemical reaction on the target surface during film formation is further promoted.

In the case where the refiner is provided near a gas inlet, the length of a pipe between the refiner and the film forming chamber 206b is less than or equal to 10 m, preferably less than or equal to 5 m and further preferably less than or equal to 1 m. When the length of the pipe is less than or equal to 10 m, less than or equal to 5 m, or less than or equal to 1 m, the effect of the release of gas from the pipe can be reduced accordingly. As the pipe for the gas, a metal pipe the inside of which is covered with iron fluoride, aluminum oxide, chromium oxide, or the like can be used. With the above pipe, the amount of released gas containing impurities is made small and the entry of impurities into the gas can be reduced as compared with a SUS316L-EP pipe, for example. Furthermore, a high-performance ultra-compact metal gasket joint (UPG joint) may be used as a joint of the pipe. A structure in which all the materials of the pipe are metals is preferable because the effect of the generated released gas or the external leakage can be reduced as compared with a structure that uses a resin or the like.

The film forming chamber 206b is connected to a turbo molecular pump 272 and a vacuum pump 270 through valves. The valves are preferably disposed at a position that is close to the substrate holder 268 and far from the target holder 266, for example. Note that although not shown, the film forming chamber 206b is preferably further connected to another turbo molecular pump and another vacuum pump through different valves. The adjustment of the valve position enables precise control of the concentration gradient of the gas in the film forming chamber 206b.

In addition, the film forming chamber 206b is provided with a cryotrap 251. The cryotrap 251 may be provided outside the film forming chamber 206b; in this case, a pipe for the connection between the film forming chamber 206b and the cryotrap 251 is additionally provided, for example.

The cryotrap 251 is a mechanism which can adsorb a molecule (or an atom) having a relatively high melting point, such as water. The turbo molecular pump 272 is capable of stably removing a large-sized molecule (or atom), needs low frequency of maintenance, and thus enables high productivity, whereas it has a low capability in removing hydrogen and water. Hence, the cryotrap 251 is provided in the film forming chamber 206b so as to have a high capability in removing water or the like. The temperature of a refrigerator of the cryotrap 251 is set to be lower than or equal to 100 K, preferably lower than or equal to 80 K. In the case where the cryotrap 251 includes a plurality of refrigerators, it is preferable to set the temperatures of the refrigerators at different temperatures because efficient exhaust is possible. For example, the temperature of a first-stage refrigerator may be set to be lower than or equal to 100 K and the temperature of a second-stage refrigerator may be set to be lower than or equal to 20 K. Note that when a titanium sublimation pump is used instead of the cryotrap, a higher vacuum can be achieved in some cases. Using an ion pump instead of a cryopump or a turbo molecular pump can also achieve higher vacuum in some cases.

Note that the exhaust method of the film forming chamber 206b is not limited to the above, and a structure similar to that in the exhaust method described above for the transfer chamber 204 (the exhaust method using the cryopump and the vacuum pump) may be employed. Needless to say, a structure similar to that of the film forming chamber 206b (the exhaust method using the turbo molecular pump and the vacuum pump) may be applied to the exhaust method of the transfer chamber 204.

Note that in each of the transfer chamber 204, the substrate heating chamber 205, and the film forming chamber 206b which are described above, the back pressure (total pressure) and the partial pressure of each gas molecule (atom) are preferably set as follows. In particular, the back pressure and the partial pressure of each gas molecule (atom) in the film forming chamber 206b need to be noted because impurities might enter a film to be formed therein.

In each of the above chambers, the back pressure (total pressure) is less than or equal to 1×10⁻⁴ Pa, preferably less than or equal to 3×10⁻⁵ Pa and further preferably less than or equal to 1×10⁻⁵ Pa. In each of the above chambers, the partial pressure of a gas molecule (atom) having a mass-to-charge ratio (m/z) of 2 is less than or equal to 1×10⁻⁵ Pa, preferably less than or equal to 3×10⁻⁶ Pa, further preferably less than or equal to 1×10⁻⁶ Pa. In each of the above chambers, the partial pressure of a gas molecule (atom) having a mass-to-charge ratio (m/z) of 18 is less than or equal to 3×10⁻⁵ Pa, preferably less than or equal to 1×10⁻⁵ Pa, further preferably less than or equal to 3×10⁻⁶ Pa. Moreover, in each of the above chambers, the partial pressure of a gas molecule (atom) having a mass-to-charge ratio (m/z) of 28 is less than or equal to 3×10⁻⁵ Pa, preferably less than or equal to 1×10⁻⁵ Pa, further preferably less than or equal to 3×10⁻⁶ Pa. Furthermore, in each of the above chambers, the partial pressure of a gas molecule (atom) having a mass-to-charge ratio (m/z) of 44 is less than or equal to 3×10⁻⁵ Pa, preferably less than or equal to 1×10⁻⁵ Pa, further preferably less than or equal to 3×10⁻⁶ Pa.

Note that a total pressure and a partial pressure in a vacuum chamber can be measured using a mass analyzer. For example, Qulee CGM-051, a quadrupole mass analyzer (also referred to as Q-mass) manufactured by ULVAC, Inc. may be used.

Moreover, the transfer chamber 204, the substrate heating chamber 205, and the film forming chamber 206b which are described above preferably have a structure with a small amount of external leakage or internal leakage.

For example, in each of the transfer chamber 204, the substrate heating chamber 205, and the film forming chamber 206b which are described above, the leakage rate is less than or equal to 3×10⁻⁶ Pa·m³/s, preferably less than or equal to 1×10⁻⁶ Pa·m³/s, further preferably less than or equal to 3×10⁻⁷ Pa·m³/s. The leakage rate of a gas molecule (atom) having a mass-to-charge ratio (m/z) of 18 is less than or equal to 1×10⁻⁷ Pa·m³/s, preferably less than or equal to 3×10⁻⁸ Pa·m³/s. The leakage rate of a gas molecule (atom) having a mass-to-charge ratio (m/z) of 28 is less than or equal to 1×10⁻⁵ Pa·m³/s, preferably less than or equal to 1×10⁻⁶ Pa·m³/s. The leakage rate of a gas molecule (atom) having a mass-to-charge ratio (m/z) of 44 is less than or equal to 3×10⁻⁶ Pa·m³/s, preferably less than or equal to 1×10⁻⁶ Pa·m³/s.

Note that a leakage rate can be derived from the total pressure and partial pressure measured using the mass analyzer.

The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or due to released gas from an internal member. Measures need to be taken from both aspects of external leakage and internal leakage in order that the leakage rates can be set to be less than or equal to the above values.

For example, an open/close portion of the film forming chamber 206b can be sealed with a metal gasket. For the metal gasket, metal covered with iron fluoride, aluminum oxide, or chromium oxide is preferably used. The metal gasket realizes higher adhesion than an O-ring, and can reduce the external leakage. Furthermore, with the use of the metal covered with iron fluoride, aluminum oxide, chromium oxide, or the like, which is in the passive state, the release of gas containing impurities released from the metal gasket is suppressed, so that the internal leakage can be reduced.

For a member of the film forming apparatus 200, aluminum, chromium, titanium, zirconium, nickel, or vanadium, which releases a smaller amount of gas containing impurities, is used. Alternatively, for the above member, an alloy containing iron, chromium, nickel, and the like covered with the above material may be used. The alloy containing iron, chromium, nickel, and the like is rigid, resistant to heat, and suitable for processing. Here, when surface unevenness of the member is decreased by polishing or the like to reduce the surface area, the release of gas can be reduced.

Alternatively, the above member of the film forming apparatus 200 may be covered with iron fluoride, aluminum oxide, chromium oxide, or the like.

The member of the film forming apparatus 200 is preferably formed using only metal when possible. For example, in the case where a viewing window formed with quartz or the like is provided, it is preferable that the surface of the viewing window be thinly covered with iron fluoride, aluminum oxide, chromium oxide, or the like so as to suppress release of gas.

When an adsorbed substance is present in the film forming chamber, the adsorbed substance does not affect the pressure in the film forming chamber because it is adsorbed onto an inner wall or the like; however, the adsorbed substance causes gas to be released when the inside of the film forming chamber is evacuated. Therefore, although there is no correlation between the leakage rate and the exhaust rate, it is important that the adsorbed substance present in the film forming chamber be desorbed as much as possible and exhaust be performed in advance with the use of a pump with high exhaust capability. Note that the film forming chamber may be subjected to baking to promote desorption of the adsorbed substance. By the baking, the desorption rate of the adsorbed substance can be increased about tenfold. The baking can be performed at a temperature higher than or equal to 100° C. and lower than or equal to 450° C. At this time, when the adsorbed substance is removed while an inert gas is introduced to the film forming chamber, the desorption rate of water or the like, which is difficult to be desorbed simply by exhaust, can be further increased. Note that when the inert gas which is introduced is heated to substantially the same temperature as the baking temperature, the desorption rate of the adsorbed substance can be further increased. Here, a rare gas is preferably used as an inert gas. Depending on the kind of a film to be formed, oxygen or the like may be used instead of an inert gas. For example, in forming an oxide, the use of oxygen which is the main component of the oxide is preferable in some cases. The baking is preferably performed using a lamp.

Alternatively, treatment for evacuating the inside of the film forming chamber is preferably performed a certain period of time after heated oxygen, a heated inert gas such as a heated rare gas, or the like is introduced to increase the pressure in the film forming chamber. The introduction of the heated gas can desorb the adsorbed substance in the film forming chamber, and the impurities present in the film forming chamber can be reduced. Note that an advantageous effect can be achieved when this treatment is repeated twice or more and 30 times or less, preferably 5 times or more and 15 times or less. Specifically, an inert gas, oxygen, or the like with a temperature higher than or equal to 40° C. and lower than or equal to 400° C., preferably higher than or equal to 50° C. and lower than or equal to 200° C., is introduced to the film forming chamber, so that the pressure therein can be kept to be greater than or equal to 0.1 Pa and less than or equal to 10 kPa, preferably greater than or equal to 1 Pa and less than or equal to 1 kPa, and further preferably greater than or equal to 5 Pa and less than or equal to 100 Pa, for a period of time ranging from 1 minute to 300 minutes, preferably from 5 minutes to 120 minutes. After that, the inside of the film forming chamber is evacuated for a period of time ranging from 5 minutes to 300 minutes, preferably from 10 minutes to 120 minutes.

The desorption rate of the adsorbed substance can be further increased also by dummy film formation. Here, the dummy film formation refers to forming a film on a dummy substrate by a sputtering method or the like, in which the film is deposited on the dummy substrate and the inner wall of the film forming chamber so that impurities in the film forming chamber and an adsorbed substance on the inner wall of the film forming chamber are confined in the film. As a dummy substrate, a substrate which releases a small amount of gas is preferably used. By performing dummy film formation, the concentration of impurities in a film to be formed later can be reduced. Note that the dummy film formation may be performed at the same time as the baking.

The surface temperature of the target is set to be lower than or equal to 100° C., preferably lower than or equal to 50° C. and further preferably about room temperature (typically 25° C.). In a sputtering apparatus for a large substrate, a large target is often used. However, it is difficult to form a target for a large substrate without a juncture. In reality, a plurality of targets are arranged so that there is as little space as possible therebetween to obtain a large shape; however, a slight space inevitably exists. When the surface temperature of the target increases, in some cases, zinc or the like is volatilized from such a slight space and the space might gradually expand. When the space expands, a metal of a backing plate or a metal contained in a bonding agent used for adhesion of the backing plate to a target might be sputtered and this might cause an increase in impurity concentration. Thus, it is preferable that the target be cooled sufficiently.

To efficiently cool the target, a metal having high conductivity and a high heat dissipation property (specifically copper) is used for the backing plate, or a sufficient amount of cooling water is made to flow through a water channel formed in the backing plate.

Note that in the case where the target contains zinc, plasma damage is alleviated by forming a film in an oxygen gas atmosphere; thus, an oxide in which zinc is unlikely to be volatilized can be obtained.

The above-described film forming apparatus enables film formation of an oxide whose hydrogen concentration measured by secondary ion mass spectrometry (SIMS) is lower than or equal to 2×10²⁰ atoms/cm³, preferably lower than or equal to 5×10¹⁹ atoms/cm³, further preferably lower than or equal to 1×10¹⁹ atoms/cm³, and still further preferably lower than or equal to 5×10¹⁸ atoms/cm³.

Furthermore, an oxide whose nitrogen concentration measured by SIMS is lower than 5×10¹⁹ atoms/cm³, preferably lower than or equal to 1×10¹⁹ atoms/cm³, further preferably lower than or equal to 5×10¹⁸ atoms/cm³, and still further preferably lower than or equal to 1×10¹⁸ atoms/cm³ can be formed.

Moreover, an oxide whose carbon concentration measured by SIMS is lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³ can be formed.

The oxide having small amounts of impurities and oxygen vacancies has low carrier density (specifically, lower than 8×10¹¹/cm³, preferably lower than 1×10¹¹/cm³, and further preferably lower than 1×10¹⁰/cm³, and is higher than or equal to 1×10⁻⁹/cm³). Such an oxide is referred to as a highly purified intrinsic or substantially highly purified intrinsic oxide. A CAAC-OS has a low impurity concentration and a low density of defect states. Thus, the CAAC-OS can be referred to as an oxide having stable characteristics.

Furthermore, an oxide can be formed in which the released amount of each of the following gas molecules (atoms) measured by thermal desorption spectroscopy (TDS) is less than or equal to 1×10¹⁹/cm³, preferably less than or equal to 1×10¹⁸/cm³:a gas molecule (atom) having a mass-to-charge ratio (m/z) of 2 (e.g., a hydrogen molecule), a gas molecule (atom) having a mass-to-charge ratio (m/z) of 18, a gas molecule (atom) having a mass-to-charge ratio (m/z) of 28, and a gas molecule (atom) having a mass-to-charge ratio (m/z) of 44.

When film formation is performed in the film forming chamber 206b, a potential is applied to the target holder 266 from the power source 291a. Furthermore, a potential is applied to the substrate holder 268 from the power source 291b. At this time, the potential of an inner wall of the film forming chamber 206b is set at a ground potential, for example. When the pressure inside the film forming chamber 206b is set to be higher than or equal to 0.05 Pa and lower than or equal to 2.00 Pa, preferably higher than or equal to 0.10 Pa and lower than or equal to 0.80 Pa and a negative potential (a potential lower than the ground potential) is applied from the power source 291a, plasma is generated in the vicinity of the target holder 266. At this time, the plasma potential is higher than the potential of the target holder 266 and accordingly cations in the plasma are accelerated toward the target holder 266. Furthermore, because the plasma potential is higher than the ground potential in many cases, cations in the plasma are also accelerated toward the places having the ground potential. The cations in the plasma accelerated toward the substrate holder 268 cause damage. Therefore, the potential that is the same as or higher than the plasma potential is preferably applied to the substrate holder 268 from the power source 291b. In this way, damage during film formation can be reduced.

Note that by setting the pressure at the film formation to be low, the potential difference between the plasma potential and the potential applied to the target holder 266 can be large. To make a large potential difference, the pressure at the film formation is set to be, for example, lower than 0.4 Pa, preferably lower than 0.2 Pa, further preferably 0.1 Pa. This enables collision of cations having high energy to the target, which leads to formation of sputtered particles having high energy. With high energy of sputtered particles, a highly crystalline oxide can be formed. In addition, the sputtering rate can be increased.

Next, the details of the transfer chamber 204 and the load lock chamber 203a illustrated in FIG. 2B and the atmosphere-side substrate transfer chamber 202 and the atmosphere-side substrate supply chamber 201 illustrated in FIG. 2C are described below. Note that FIG. 2C shows a cross section of the atmosphere-side substrate transfer chamber 202 and the atmosphere-side substrate supply chamber 201.

For the transfer chamber 204 illustrated in FIG. 2B, refer to the description of the transfer chamber 204 illustrated in FIG. 2A.

The load lock chamber 203a includes a substrate delivery stage 252. When the pressure in the load lock chamber 203a becomes atmospheric pressure by being increased from reduced pressure, the substrate delivery stage 252 receives a substrate from the transfer robot 263 provided in the atmosphere-side substrate transfer chamber 202. After that, the load lock chamber 203a is evacuated into vacuum so that the pressure therein becomes reduced pressure and then the transfer robot 263 provided in the transfer chamber 204 receives the substrate from the substrate delivery stage 252.

Furthermore, the load lock chamber 203a is connected to the vacuum pump 270 and the cryopump 271 through valves. The description of the method for connecting the transfer chamber 204 can be referred to for a method for connecting exhaust systems such as the vacuum pump 270 and the cryopump 271, and the description thereof is omitted here. Note that the unload lock chamber 203b illustrated in FIG. 1 can have a structure similar to that in the load lock chamber 203a.

The atmosphere-side substrate transfer chamber 202 includes the transfer robot 263. The transfer robot 263 can deliver a substrate from the cassette port 261 to the load lock chamber 203a or deliver a substrate from the load lock chamber 203a to the cassette port 261. Furthermore, a mechanism for suppressing entry of dust or a particle, such as high efficiency particulate air (HEPA) filter, may be provided above the atmosphere-side substrate transfer chamber 202 and the atmosphere-side substrate supply chamber 201.

The atmosphere-side substrate supply chamber 201 includes a plurality of cassette ports 261. The cassette ports 261 can hold a plurality of substrates.

With the above film forming apparatus, entry of impurities into the oxide can be suppressed. Furthermore, when a film in contact with the oxide is formed with the use of the above film forming apparatus, the entry of impurities into the oxide from the film in contact therewith can be suppressed. Moreover, a highly crystalline oxide can be formed.

### <Film Forming Apparatus 2>

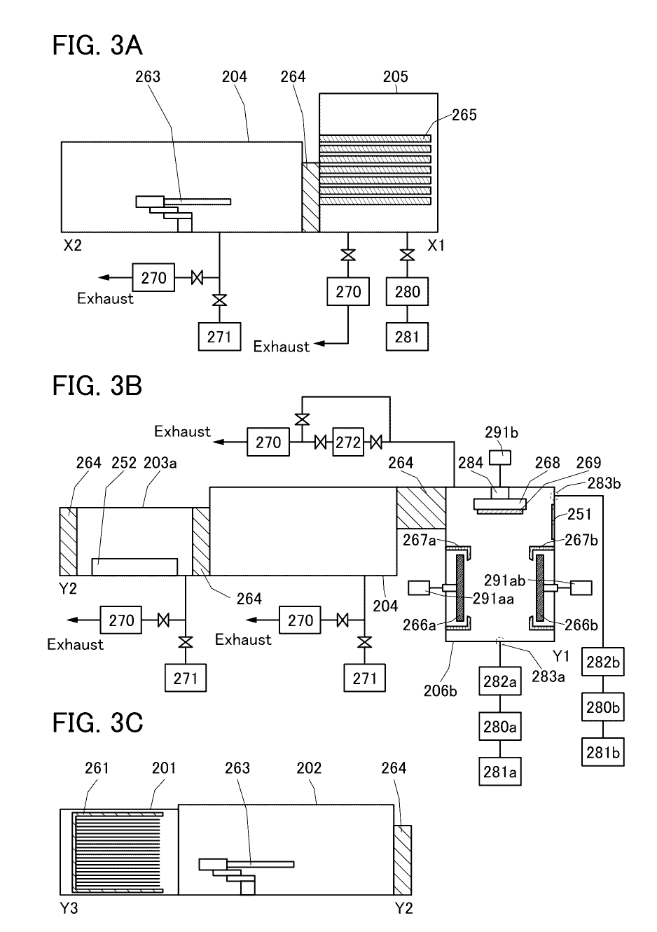

A film forming apparatus including a film forming chamber having a different structure from the film forming chamber included in the film forming apparatus illustrated in FIG. 1 and FIGS. 2A to 2C is described below with reference to FIGS. 3A to 3C.

Like FIGS. 2A to 2C, FIG. 3A illustrates a cross section of the substrate heating chamber 205 and the transfer chamber 204, FIG. 3B illustrates a cross section of the film forming chamber 206b, the transfer chamber 204, and the load lock chamber 203a, and FIG. 3C illustrates a cross section of the atmosphere-side substrate transfer chamber 202 and the atmosphere-side substrate supply chamber 201. The film forming apparatus illustrated in FIGS. 3A to 3C is different from the film forming apparatus illustrated in FIGS. 2A to 2C only in the structure of the film forming chamber 206b illustrated in FIG. 3B, and other structures are similar to those in FIGS. 2A to 2C. Thus, for the structure of the film forming apparatus illustrated in FIGS. 3A to 3C, descriptions of the film forming apparatus illustrated in FIGS. 2A to 2C can be referred to.

The film forming chamber 206b illustrated in FIG. 3B is different from the film forming chamber 206b illustrated in FIG. 2B in including a target holder 266a, a target holder 266b, a member 267a, a member 267b, a power source 291aa, and a power source 291ab. Furthermore, the power source 291aa is electrically connected to the target holder 266a. The power source 29 lab is electrically connected to the target holder 266b. The member 267a is provided to cover an edge of the target holder 266a. The member 267b is provided to cover an edge of the target holder 266b. The member 267a and the member 267b have a function of a target shield. As in the film forming chamber 206b illustrated in FIG. 2B, the distance between the target holder 266a and the substrate holder 268 and between the target holder 266b and the substrate holder 268 can be changed by the member 284. Moreover, a resistor may be provided above the target holder 266a and/or the target holder 266b.

Also in the film forming chamber 206b illustrated in FIG. 3B, the first inlet 283a and the second inlet 283b are preferably disposed separate from each other. For example, the first inlet 283a is disposed at a position that is closer to the target holders 266a and 266b than to the substrate holder 268 and the second inlet 283b is disposed at a position that is closer to the substrate holder 268 than to the target holders 266a and 266b. By this disposition, an introduced gas has a concentration gradient between the target holders 266a and 266b and the substrate holder 268. Specifically, by introducing an oxygen gas from the first inlet 283a and introducing argon from the second inlet 283b, a concentration gradient in which the proportion of oxygen increases (the proportion of argon decreases) from the substrate holder 268 toward the target holders 266a and 266b can be made. By this concentration gradient, stable plasma generation is possible in some cases while oxidation reaction is promoted in the vicinity of the target surface during film formation. Furthermore, it is preferable in some cases that the gas introduced from the first inlet 283a and/or the second inlet 283b be heated. For example, by heating the gas introduced from the first inlet 283a, a chemical reaction on the target surface during film formation is further promoted.

The film forming chamber 206b illustrated in FIG. 3B is also connected to the turbo molecular pump 272 and the vacuum pump 270 through valves. The valves are preferably disposed at a position that is close to the substrate holder 268 and far from the target holders 266a and 266b, for example. Note that although not shown, the film forming chamber 206b is preferably further connected to another turbo molecular pump and another vacuum pump through different valves. The adjustment of the valve position enables precise control of the concentration gradient of the gas in the film forming chamber 206b.

When film formation is performed in the film forming chamber 206b illustrated in FIG. 3B, a potential is applied to the target holder 266a from the power source 291aa and also applied to the target holder 266b from the power source 291ab. Furthermore, a potential is applied to the substrate holder 268 from the power source 291b. At this time, the potential of an inner wall of the film forming chamber 206b is set at a ground potential, for example. When the pressure inside the film forming chamber 206b is set to be higher than or equal to 0.05 Pa and lower than or equal to 2.00 Pa, preferably higher than or equal to 0.10 Pa and lower than or equal to 0.80 Pa and a negative potential (a potential lower than the ground potential) is applied from the power source 291a, plasma is generated in the vicinity of the target holders 266a and 266b. At this time, the plasma potential is higher than the potentials of the target holders 266a and 266b and accordingly cations in the plasma are accelerated toward the target holders 266a and 266b. Furthermore, because the plasma potential is higher than the ground potential in many cases, cations in the plasma are also accelerated toward the places having the ground potential. The cations in the plasma accelerated toward the substrate holder 268 cause damage. Therefore, the potential that is the same as or higher than the plasma potential is preferably applied to the substrate holder 268 from the power source 291b. In this way, damage during film forming can be reduced.

Note that by setting the pressure at the film formation to be low, the potential difference between the plasma potential and the potentials applied to the target holders 266a and 266b can be large. To make a large potential difference, the pressure at the film formation is set to be, for example, lower than 0.4 Pa, preferably lower than 0.2 Pa, further preferably 0.1 Pa. This enables collision of cations having high energy to the target, which leads to formation of sputtered particles having high energy. With high energy of sputtered particles, a highly crystalline oxide can be formed. In addition, the sputtering rate can be increased.

With the above film forming apparatus, entry of impurities into the oxide can be suppressed. Furthermore, when a film in contact with the oxide is formed with the use of the above film forming apparatus, the entry of impurities into the oxide from the film in contact therewith can be suppressed. Moreover, a highly crystalline oxide can be formed.

### <Sputtering Apparatus 1>

A parallel-plate sputtering apparatus of one embodiment of the present invention will be described below. The sputtering apparatus described in this section can be used in the film forming chambers 206a, 206b, 206c, and the like of the film forming apparatus illustrated in FIG. 1 and FIGS. 2A to 2C, for example. For easy understanding or the explanation of the operation during film formation, the following descriptions of the sputtering apparatuses are made on the assumption that a substrate, a target, and the like are provided. Note that the substrate, the target, and the like are provided by a user; thus, the sputtering apparatus of one embodiment of the present invention does not necessarily include the substrate and the target.

Film formation using a parallel-plate sputtering apparatus can also be referred to as parallel electrode sputtering (PESP).

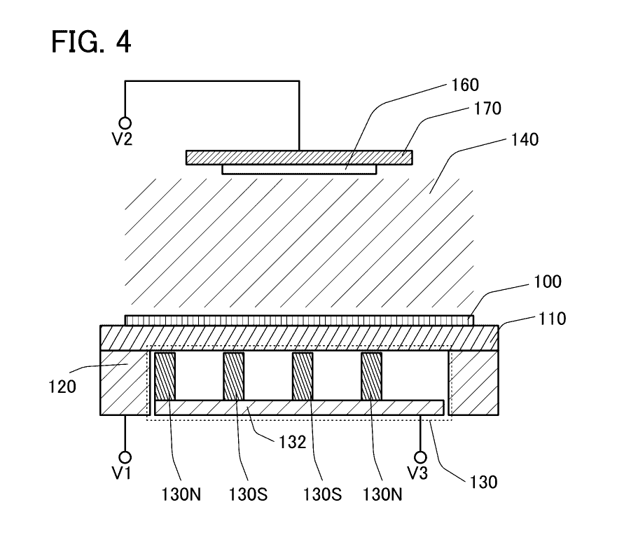

FIG. 4 is a cross-sectional view of a film forming chamber including a parallel-plate sputtering apparatus. The film forming chamber in FIG. 4 includes a target holder 120, a backing plate 110, a target 100, a magnet unit 130, and a substrate holder 170. Note that the target 100 is placed over the backing plate 110. The backing plate 110 is placed over the target holder 120. The magnet unit 130 is placed under the target 100 with the backing plate 110 positioned therebetween. The substrate holder 170 faces the target 100. Note that in this specification, a magnet unit means a group of magnets. The magnet unit can be replaced with “cathode,” “cathode magnet,” “magnetic member,” “magnetic part,” or the like. The magnet unit 130 includes a magnet 130N, a magnet 130S, and a magnet holder 132. Note that in the magnet unit 130, the magnet 130N and the magnet 130S are placed over the magnet holder 132. The magnet 130N and the magnet 130S are spaced. When a substrate 160 is transferred into the film forming chamber, the substrate 160 is placed on the substrate holder 170.

The target holder 120 and the backing plate 110 are fixed to each other with a bolt and have the same potential. The target holder 120 has a function of supporting the target 100 with the backing plate 110 positioned therebetween.

The target 100 is fixed to the backing plate 110. The target 100 can be fixed to the backing plate 110 using a bonding agent containing a low-melting-point metal such as indium, for example.

The film forming chamber may have a water channel inside or under the backing plate 110. By letting fluid (air, nitrogen, a rare gas, water, oil, or the like) flow through the water channel, discharge anomaly due to an increase in the temperature of the target 100 or damage to the film forming chamber due to deformation of a component can be prevented in the sputtering. In that case, the backing plate 110 and the target 100 are preferably adhered to each other with a bonding agent because the cooling capability is increased.

A gasket is preferably provided between the target holder 120 and the backing plate 110, in which case an impurity is less likely to enter the film forming chamber from the outside or the water channel.

In the magnet unit 130, the magnet 130N and the magnet 130S are placed such that their surfaces on the target 100 side have opposite polarities. Here, the case where the pole of the magnet 130N on the target 100 side is the north pole and the pole of the magnet 130S on the target 100 side is the south pole is described. Note that the layout of the magnets and the poles in the magnet unit 130 are not limited to those described here or those illustrated in FIG. 4.

A method of forming a film on the substrate 160 is described below.

First, a film forming gas is supplied to a film forming chamber kept at a high vacuum and the pressure is adjusted by a vacuum pump.

Next, a potential V1 is applied to a terminal V1 connected to the target holder 120. Note that the target holder 120 is electrically connected to the backing plate 110; therefore, they both have the same potentials. Thus, plasma 140 is generated between the target 100 and the substrate 160. The potential V1 may be, for example, lower than a potential V2 applied to a terminal V2 connected to the substrate holder 170. At this time, the potential V2 applied to the terminal V2 connected to the substrate holder 170 is, for example, higher than the ground potential. A potential V3 applied to a terminal V3 connected to the magnet holder 132 is, for example, the ground potential. Note that the potentials applied to the terminals V1, V2, and V3 are not limited to the above description. For example, the substrate holder 170 may be electrically floating. Note that it is assumed that a power source capable of controlling a potential applied to the terminal V1 is electrically connected to the terminal V1. As the power source, a DC power source or an RF power source may be used.

The magnet unit 130 preferably has a structure which makes the maximum magnetic flux density in a direction perpendicular to a front surface (surface on the target side) of the target holder 120 more than or equal to 50 G and less than or equal to 150 G at a plane that is 30 mm away in the perpendicular direction from the front surface of the target holder 120. By setting the maximum magnetic flux density to be low, the potential difference between the plasma potential and the potential applied to the target holder 120 can be large. This enables collision of cations having high energy to the target, which leads to formation of sputtered particles having high energy. With high energy of sputtered particles, a highly crystalline oxide can be formed. In addition, the sputtering rate can be increased.

When the partial pressure of oxygen in the film forming gas is too high, an oxide including a plurality of kinds of crystal phases is likely to be formed; therefore, a mixed gas of oxygen and a rare gas such as argon (other examples of the rare gas are helium, neon, krypton, and xenon) is preferably used as the film forming gas. For example, the proportion of oxygen in the whole film forming gas is less than 50 vol %, preferably less than or equal to 33 vol %, further preferably less than or equal to 20 vol %, and still further preferably less than or equal to 15 vol %.

The vertical distance between the target 100 and the substrate 160 is greater than or equal to 10 mm and less than or equal to 600 mm, preferably greater than or equal to 20 mm and less than or equal to 400 mm, further preferably greater than or equal to 30 mm and less than or equal to 200 mm, and still further preferably greater than or equal to 40 mm and less than or equal to 100 mm. The short vertical distance between the target 100 and the substrate 160 within the above-described range can sometimes suppress a decrease in the energy of the sputtered particles until the sputtered particles reach the substrate 160. The long vertical distance between the target 100 and the substrate 160 within the above-described range allows the incident direction of the sputtered particles to be approximately vertical to the substrate 160, so that damage to the substrate 160 caused by collision of the sputtered particles can be reduced in some cases.

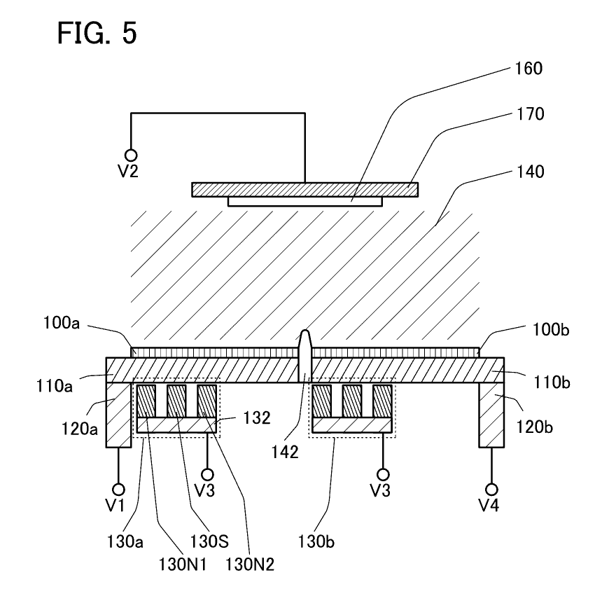

FIG. 5 illustrates an example of a film forming chamber including a sputtering apparatus, which is different from that in FIG. 4.

The film forming chamber in FIG. 5 includes a target holder 120a, a target holder 120b, a backing plate 110a, a backing plate 110b, a target 100a, a target 100b, a magnet unit 130a, a magnet unit 130b, a member 142, and the substrate holder 170. Note that the target 100a is placed over the backing plate 110a. The backing plate 110a is placed over the target holder 120a. The magnet unit 130a is placed under the target 100a with the backing plate 110a positioned therebetween. The target 100b is placed over the backing plate 110b. The backing plate 110b is placed over the target holder 120b. The magnet unit 130b is placed under the target 100b with the backing plate 110b positioned therebetween.

The magnet unit 130a includes a magnet 130N1, a magnet 130N2, the magnet 130S, and the magnet holder 132. Note that in the magnet unit 130a, the magnet 130N1, the magnet 130N2, and the magnet 130S are placed over the magnet holder 132. The magnet 130N1, the magnet 130N2, and the magnet 130S are spaced. Note that the magnet unit 130b has a structure similar to that of the magnet unit 130a. When the substrate 160 is transferred into the film forming chamber, the substrate 160 is placed on the substrate holder 170.

The target 100a, the backing plate 110a, and the target holder 120a are separated from the target 100b, the backing plate 110b, and the target holder 120b by the member 142. Note that the member 142 is preferably an insulator. The member 142 may be a conductor or a semiconductor. The member 142 may be a conductor or a semiconductor whose surface is covered with an insulator.

The target holder 120a and the backing plate 110a are fixed to each other with a bolt and have the same potential. The target holder 120a has a function of supporting the target 100a with the backing plate 110a positioned therebetween. The target holder 120b and the backing plate 110b are fixed to each other with a bolt and have the same potential. The target holder 120b has a function of supporting the target 100b with the backing plate 110b positioned therebetween.

The backing plate 110a has a function of fixing the target 100a. The backing plate 110b has a function of fixing the target 100b.

In the magnet unit 130a, for example, the rectangular or substantially rectangular magnet 130N1, the rectangular or substantially rectangular magnet 130N2, and the rectangular or substantially rectangular magnet 130S are fixed to the magnet holder 132. The same structure applies to the magnet unit 130b.

In the magnet unit 130a, the magnets 130N1 and 130N2 and the magnet 130S are placed such that their surfaces on the target 100a side have opposite polarities. Here, the case where the pole of each of the magnets 130N1 and 130N2 on the target 100a side is the north pole and the pole of the magnet 130S on the target 100a side is the south pole is described. Note that the layout of the magnets and the poles in the magnet unit 130a are not limited to those described here or those illustrated in FIG. 5. The same applies to the magnet unit 130b.

The film forming chamber may have a water channel inside or under the backing plates 110a and 110b. By letting fluid (air, nitrogen, a rare gas, water, oil, or the like) flow through the water channel, discharge anomaly due to an increase in the temperature of the target 100a and the target 100b or damage to the film forming chamber due to deformation of a component can be prevented in the sputtering. In that case, the backing plate 110a and the target 100a are preferably adhered to each other with a bonding agent because the cooling capability is increased. Furthermore, the backing plate 110b and the target 100b are preferably adhered to each other with a bonding agent because the cooling capability is increased.

A gasket is preferably provided between the target holder 120a and the backing plate 110a, in which case an impurity is less likely to enter the film forming chamber from the outside or the water channel. A gasket is preferably provided between the target holder 120b and the backing plate 110b, in which case an impurity is less likely to enter the film forming chamber from the outside or the water channel.

During the film formation, a potential V1 applied to a terminal V1 connected to the target holder 120a and a potential V4 applied to a terminal V4 connected to the target holder 120b may be alternately switched between a high level and a low level. When the potential V1 is one of the high level and the low level, the potential V4 is the other of the high level and the low level. A potential V2 applied to a terminal V2 connected to the substrate holder 170 is, for example, higher than the ground potential. A potential V3 applied to a terminal V3 connected to the magnet holder 132 is, for example, the ground potential. Note that the potentials applied to the terminals V1, V2, V3, and V4 are not limited to the above description. Not all the target holder 120a, the target holder 120b, the substrate holder 170, and the magnet holder 132 are necessarily supplied with potentials. For example, the substrate holder 170 may be electrically floating. Note that although the potential applied to the terminal V1 connected to the target holder 120a and the potential applied to the terminal V4 connected to the target holder 120b are alternately switched between the high level and the low level (i.e., an AC sputtering method) in the example illustrated in FIG. 5, one embodiment of the present invention is not limited thereto.

FIG. 5 illustrates an example where the backing plate 110a and the target holder 120a are not electrically connected to the magnet unit 130a or the magnet holder 132, but electrical connection is not limited thereto. For example, the backing plate 110a and the target holder 120a may be electrically connected to the magnet unit 130a and the magnet holder 132, and the backing plate 110a, the target holder 120a, the magnet unit 130a, and the magnet holder 132 may have the same potential. The backing plate 110b and the target holder 120b are not electrically connected to the magnet unit 130b or the magnet holder 132 in the example, but electrical connection is not limited thereto. For example, the backing plate 110b and the target holder 120b may be electrically connected to the magnet unit 130b and the magnet holder 132, and the backing plate 110b, the target holder 120b, the magnet unit 130b, and the magnet holder 132 may have the same potential.

To increase the crystallinity of the formed oxide, the temperature of the substrate 160 may be set high. By setting the temperature of the substrate 160 high, migration of sputtered particles at the top surface of the substrate 160 can be promoted. Thus, an oxide with higher density and higher crystallinity can be formed. Note that the temperature of the substrate 160 is, for example, higher than or equal to 100° C. and lower than or equal to 450° C., preferably higher than or equal to 150° C. and lower than or equal to 400° C., and further preferably higher than or equal to 170° C. and lower than or equal to 350° C.

When the partial pressure of oxygen in the film forming gas is too high, an oxide including a plurality of kinds of crystal phases is likely to be formed; therefore, a mixed gas of oxygen and a rare gas such as argon (other examples of the rare gas are helium, neon, krypton, and xenon) is preferably used as the film forming gas. For example, the proportion of oxygen in the whole film forming gas is less than 50 vol %, preferably less than or equal to 33 vol %, further preferably less than or equal to 20 vol %, and still further preferably less than or equal to 15 vol %.

The vertical distance between the target 100a and the substrate 160 is greater than or equal to 10 mm and less than or equal to 600 mm, preferably greater than or equal to 20 mm and less than or equal to 400 mm, further preferably greater than or equal to 30 mm and less than or equal to 200 mm, and still further preferably greater than or equal to 40 mm and less than or equal to 100 mm. The short vertical distance between the target 100a and the substrate 160 within the above-described range can suppress a decrease in the energy of the sputtered particles until the sputtered particles reach the substrate 160, in some cases. The long vertical distance between the target 100a and the substrate 160 within the above-described range allows the incident direction of the sputtered particles to be approximately vertical to the substrate 160, so that damage to the substrate 160 caused by collision of the sputtered particles can be reduced in some cases.

The vertical distance between the target 100b and the substrate 160 is greater than or equal to 10 mm and less than or equal to 600 mm, preferably greater than or equal to 20 mm and less than or equal to 400 mm, further preferably greater than or equal to 30 mm and less than or equal to 200 mm, and still further preferably greater than or equal to 40 mm and less than or equal to 100 mm. The short vertical distance between the target 100b and the substrate 160 within the above-described range can suppress a decrease in the energy of the sputtered particles until the sputtered particles reach the substrate 160, in some cases. The long vertical distance between the target 100b and the substrate 160 within the above-described range allows the incident direction of the sputtered particles to be approximately vertical to the substrate 160, so that damage to the substrate 160 caused by collision of the sputtered particles can be reduced in some cases.

### <Sputtering Apparatus 2>

A facing-target sputtering apparatus which has a different structure from the above-described parallel-plate sputtering apparatus will be described below. The sputtering apparatus described in this section can be used in the film forming chambers 206a, 206b, 206c, and the like of the film forming apparatus illustrated in FIG. 1 and FIGS. 3A to 3C, for example. For easy understanding or the explanation of the operation during film formation, the following descriptions of the sputtering apparatuses are made on the assumption that a substrate, a target, and the like are provided. Note that the substrate, the target, and the like are provided by a user; thus, the sputtering apparatus of one embodiment of the present invention does not necessarily include the substrate and the target.

Film formation using a facing-target sputtering apparatus can also be referred to as vapor deposition sputtering (VDSP).

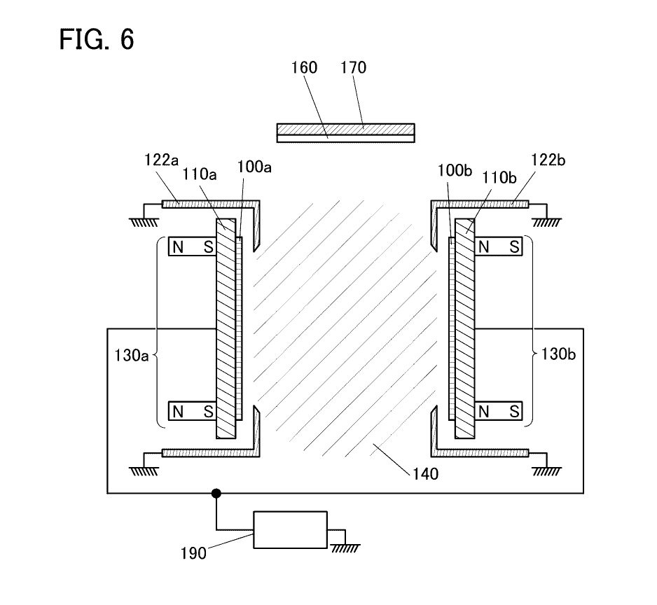

FIG. 6 illustrates an example of a cross-sectional view of a film forming chamber including a sputtering apparatus. FIG. 6 illustrates a facing-target sputtering apparatus.

FIG. 6 is a schematic cross-sectional view of a film forming chamber. The film forming chamber illustrated in FIG. 6 includes the target 100a, the target 100b, the backing plate 110a for holding the target 100a, the backing plate 110b for holding the target 100b, the magnet unit 130a placed on a back side of the target 100a with the backing plate 110a positioned therebetween, and the magnet unit 130b placed on a back side of the target 100b with the backing plate 110b positioned therebetween. Furthermore, a member 122a which covers an edge of the backing plate 110a and a member 122b which covers an edge of the backing plate 110b are included. The member 122a and the member 122b have a function of a target shield. The substrate holder 170 is placed between the target 100a and the target 100b. When the substrate 160 is transferred into the film forming chamber, the substrate 160 is fixed with the substrate holder 170.

Although not shown, the backing plate 110a (the backing plate 110b) is fixed to the target holder with a bolt and have the same potential. The target holder has a function of supporting the target 100a (target 100b) with the backing plate 110a (backing plate 110b) positioned therebetween.

The target 100a (target 100b) is fixed to the backing plate 110a (backing plate 110b). The target 100a (target 100b) can be fixed to the backing plate 110a (backing plate 110b), using a bonding material containing a low-melting-point metal such as indium, for example.

The film forming chamber may have a water channel inside or under the backing plate 110a (backing plate 110b). By making fluid (air, nitrogen, a rare gas, water, oil, or the like) flow through the water channel, discharge anomaly due to an increase in the temperature of the target 100a (target 100b) or damage to the film forming chamber due to deformation of a component can be prevented in the sputtering. In that case, the backing plate 110a (backing plate 110b) and the target 100a (target 100b) are preferably adhered to each other with a bonding agent because the cooling capability is increased.

A gasket is preferably provided between the target holder and the backing plate 110a (backing plate 110b), in which case an impurity is less likely to enter the film forming chamber from the outside or the water channel.

As illustrated in FIG. 6, a power source 190 for applying potentials are connected to the backing plates 110a and 110b. Furthermore, the potentials of the member 122a and the member 122b are preferably set at a ground potential, in a manner similar to that of the inner wall of the film forming chamber. It is preferable to use an AC power source which alternately applies a high level potential and a low level potential to the backing plate 110a and the backing plate 110b. When one of the high level potential and the low level potential is applied to the backing plate 110a, the other of the high level potential and the low level potential is applied to the backing plate 110b. Although an AC power source is used as the power source 190 illustrated in FIG. 6, one embodiment of the present invention is not limited thereto. For example, an RF power source, a DC power source, or the like can be used as the power source 190. Alternatively, different kinds of power sources may be connected to the backing plates 110a and 110b.

A potential higher than the ground potential is preferably applied to the substrate holder 170. Alternatively, the substrate holder 170 may be supplied with the ground potential or may be in a floating state.

The film formation is preferably performed in the state where the surface of the substrate 160 is not exposed to the plasma 140. A region that is away from the plasma 140 is a region where the gradient of the potential distribution is small. Because the substrate 160 is not exposed to a high electric field portion in the plasma 140, the substrate 160 has less damage due to the plasma 140 and has few defects.

In FIG. 6, the target 100a and the target 100b are parallel to each other. Moreover, the magnet unit 130a and the magnet unit 130b are placed so that opposite poles of magnets face each other. In that case, magnetic force lines are from the magnet unit 130b toward the magnet unit 130a. Thus, the plasma 140 is confined by magnetic fields formed by the magnet unit 130a and the magnet unit 130b during film formation. Note that although the substrate holder 170 and the substrate 160 are placed parallel to the direction in which the target 100a and the target 100b face each other in FIG. 6, the substrate holder 170 and the substrate 160 may be inclined to the direction. By inclination of the substrate holder 170 and the substrate 160 at 30° or more and 60° or less (typified by 45°), for example, the proportion of sputtered particles that perpendicularly reach the substrate 160 during film formation can be increased.

The magnet unit 130a (magnet unit 130b) preferably has a structure which makes the maximum magnetic flux density in a direction perpendicular to a front surface (surface on the target side) of the target holder more than or equal to 50 G and less than or equal to 150 G at a plane that is 30 mm away in the perpendicular direction from the front surface of the target holder. By setting the maximum magnetic flux density to be low, the potential difference between the plasma potential and the potential applied to the target holder can be large. This enables collision of cations having high energy to the target, which leads to formation of sputtered particles having high energy. With high energy of sputtered particles, a highly crystalline oxide can be formed. In addition, the sputtering rate can be increased.

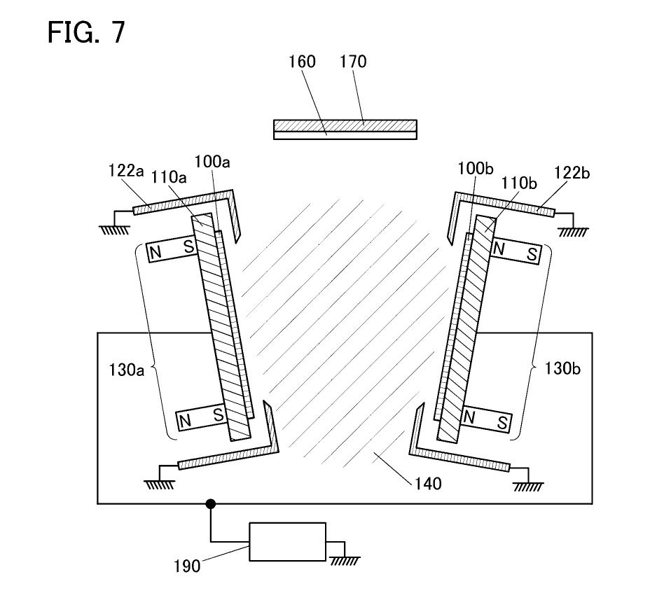

A structure illustrated in FIG. 7 is different from that illustrated in FIG. 6 in that the target 100a and the target 100b that face each other are not parallel but inclined to each other (in a V shape). Thus, for the description except for the positions of the targets, refer to the description of FIG. 6. The magnet unit 130a and the magnet unit 130b are placed so that opposite poles of magnets face each other. With the targets 100a and 100b placed as illustrated in FIG. 7, the proportion of sputtered particles that reach the substrate 160 can be increased; accordingly, the film forming rate can be increased.

The substrate holder 170 may be placed above a region between targets, or may be placed below the region. Alternatively, the substrate holders 170 may be placed above and below the region. When the substrate holders 170 are provided above and below the region, film formation on two or more substrates can be performed at once, leading to an increase in productivity. Note that the position above or below the region where the target 100a and the target 100b face each other can also be referred to as the side of the region where the target 100a and the target 100b face each other.

The facing-target sputtering apparatus can stably generate plasma even in high vacuum. Thus, film formation can be performed at a pressure higher than or equal to 0.005 Pa and lower than or equal to 0.09 Pa, for example. As a result, the concentration of impurities mixed during film formation can be reduced.

The use of the facing-target sputtering apparatus allows film formation in high vacuum or film formation with less plasma damage and thus can provide a film with high crystallinity even when the temperature of the substrate 160 is low (e.g., higher than or equal to 10° C. and lower than 100° C.).

In the above-described facing-target sputtering apparatuses, plasma is confined by magnetic fields between targets; thus, plasma damage to a substrate can be reduced. Furthermore, a formed film can have improved step coverage because an incident angle of a sputtered particle to a substrate can be made smaller by the inclination of the target. Moreover, film formation in high vacuum enables the concentration of impurities contained in the film to be reduced.

### <Composition>

The composition of an In-M-Zn oxide is described below. The element M is aluminum, gallium, yttrium, tin, or the like. Other elements which can be used as the element M are boron, silicon, titanium, iron, nickel, germanium, zirconium, molybdenum, lanthanum, cerium, neodymium, hafnium, tantalum, tungsten, magnesium, and the like.

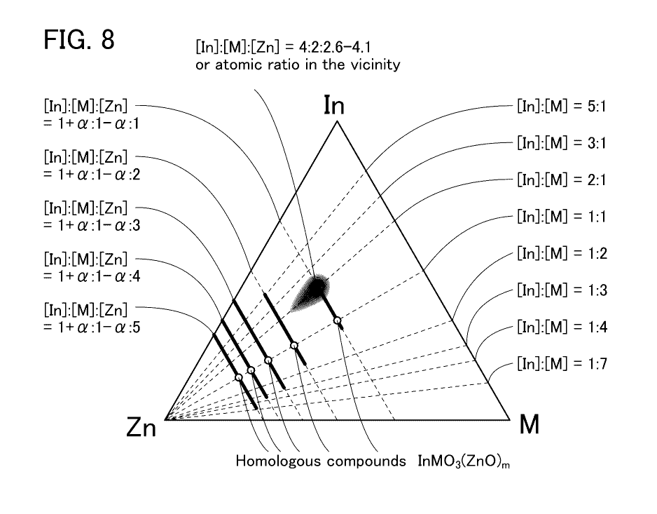

The In-M-Zn oxide can be represented by InM_{X}Xn_{Y}O_{Z} (X, Y, and Z are non-integers). FIG. 8 is a triangular diagram in which the vertices represent In, M, and Zn. In the diagram, [In] means the atomic concentration of In, [M] means the atomic concentration of the element M, and [Zn] means the atomic concentration of Zn.

An In-M-Zn oxide is largely classified into homologous compounds represented by InMO₃(ZnO)ₘ (m is an integer) and non-homologous compounds which are not represented by InMO₃(ZnO)ₘ (m is an integer). As indicated by hollow circles in FIG. 8, the composition of homologous compounds with In:M:Zn=1:1:m is very limited. Moreover, the homologous compounds are reported to have a thermal equilibrium state at a high temperature (approximately 1350° C.). However, at low temperatures, m is deviated from an integer and the homologous compounds are difficult to obtain. In contrast, a non-homologous compound can be formed by a sputtering method with substrate heating at temperatures lower than 500° C., for example, higher than or equal to 100° C. and lower than 350° C., so that a wide margin for mass production can be ensured, which is preferable.

For example, an In-M-Zn oxide represented by In₁₊ₐM₁₋ₐO₃(ZnO)ₘ (m is an integer, −1<a<1 but a≠0) obtained by replacing part of the element M with In is a kind of non-homologous compound and the oxides with such a composition are indicated by dashed lines denoted by [In]:[M]:[Zn]=1+α:1−α:1, [In]:[M]:[Zn]=1+α:1−α:2, [In]:[M]:[Zn]=1+α:1−α:3, [In]:[M]:[Zn]=1+α:1−α:4, and [In]:[M]:[Zn]=1+α:1−α:5 in FIG. 8. Note that the bold lines on the dashed lines represent, for example, the compositions that allow oxides (raw materials) to be a solid solution when the oxides are mixed and subjected to baking at 1350° C.

By setting the composition close to the above-described composition that allows the oxide to be a solid solution, even a non-homologous In-M-Zn oxide can increase its crystallinity. When an In-M-Zn oxide is formed by a sputtering method, the composition of a target is different from the composition of a film. For example, the atomic ratio In:M:Zn of the film is 1:1:0.5 to 1:1:0.9 or the ratio in the vicinity of the range, 1:1:0.8 to 1:1:1.1 or the ratio in the vicinity of the range, 3:1:1 to 3:1:1.8 or the ratio in the vicinity of the range, 4:2:2.6 to 4:2:4.1 or the ratio in the vicinity of the range, 5:1:5.5 to 5:1:6.5 or the ratio in the vicinity of the range, 1:3:1 to 1:3:1.8 or the ratio in the vicinity of the range, 1:3:2.5 to 1:3:3.5 or the ratio in the vicinity of the range, or 1:4:3.4 to 1:4:4.4 or the ratio in the vicinity of the range. To obtain a film with a desired composition, a composition of a target is selected in consideration of a change in the composition. In FIG. 8, the atomic ratios of 4:2:2.6 to 4:2:4.1 and in the vicinity of the range are shown. A transistor including the In-M-Zn oxide with the atomic ratio in this range can have stable and excellent electric characteristics.

Thus, the proportion of Zn is likely to decrease in an In-M-Zn oxide formed by a sputtering method with substrate heating at temperatures of practically lower than 500° C., for example, higher than or equal to 100° C. and lower than 350° C. Furthermore, although not as much as the proportion of Zn, the proportions of In and the element M also change; therefore, m is deviated from an integer, in other words, m becomes a non-integer. The compound with m not being an integer is not a homologous compound but a non-homologous compound. The composition of the In-M-Zn oxide which is a non-homologous compound is not limited to the range represented by In₁₊ₐM₁₋ₐO₃(ZnO)ₘ (m is an integer). For example, the composition of the In-M-Zn oxide can be represented by In₁₊ₐM₁₋ₐO₃(ZnO)ₙ (n is a non-integer within the range of m±0.2).

Moreover, the In-M-Zn oxide which is a non-homologous compound might include regions having different m values. For example, a region with m=1 and a region with m=2 might be included in an In-M-Zn oxide. Such an oxide can be represented by In₁₊ₐM₁₋ₐO₃(ZnO)ₘ with m=1.5, for example.

### <Structure of Oxide Semiconductor>

A structure of an oxide semiconductor is described below.

An oxide semiconductor is classified into a single crystal oxide semiconductor and a non-single-crystal oxide semiconductor. Examples of a non-single-crystal oxide semiconductor include a c-axis-aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and an nc-OS.

An amorphous structure is generally thought to be isotropic and have no non-uniform structure, to be metastable and not have fixed positions of atoms, to have a flexible bond angle, and to have a short-range order but have no long-range order, for example.

This means that a stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. In contrast, an a-like OS, which is not isotropic, has an unstable structure that contains a void. Because of its instability, an a-like OS is close to an amorphous oxide semiconductor in terms of physical properties.

### <CAAC-OS>

First, a CAAC-OS is described.

A CAAC-OS is one of oxide semiconductors having a plurality of c-axis aligned crystal parts (also referred to as pellets).

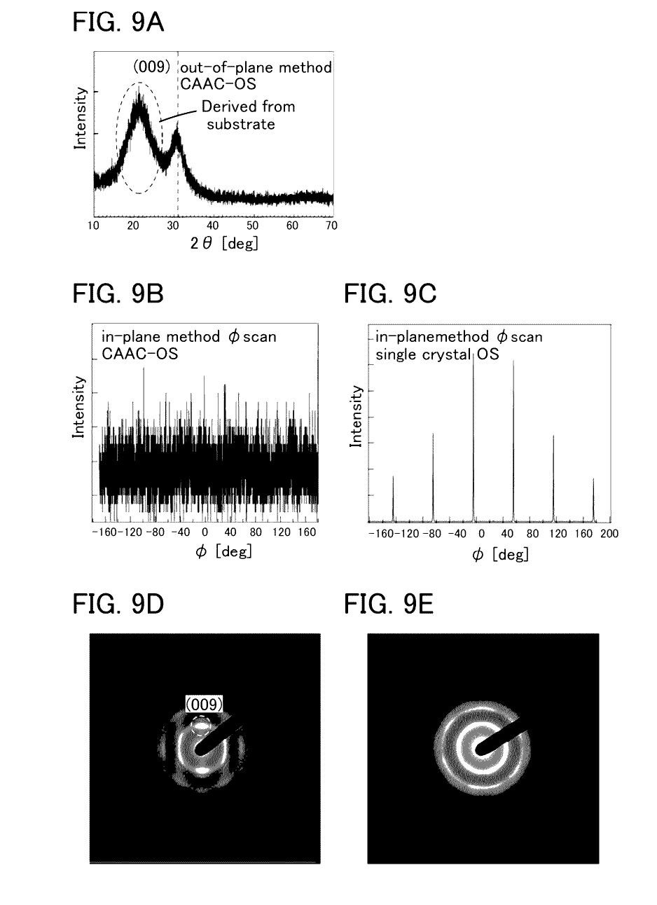

Analysis of a CAAC-OS by X-ray diffraction (XRD) is described. For example, when the structure of a CAAC-OS including an InGaZnO₄ crystal that is classified into the space group R-3m is analyzed by an out-of-plane method, a peak appears at a diffraction angle (2θ) of around 31° as shown in FIG. 9A. This peak is derived from the (009) plane of the InGaZnO₄ crystal, which indicates that crystals in the CAAC-OS have c-axis alignment, and that the c-axes are aligned in a direction substantially perpendicular to a surface over which the CAAC-OS film is formed (also referred to as a formation surface) or the top surface of the CAAC-OS film. Note that a peak sometimes appears at a 2θ of around 36° in addition to the peak at a 2θ of around 31°. The peak at a 2θ of around 36° is derived from a crystal structure that is classified into the space group Fd-3m; thus, this peak is preferably not exhibited in a CAAC-OS.

On the other hand, in structural analysis of the CAAC-OS by an in-plane method in which an X-ray is incident on the CAAC-OS in a direction parallel to the formation surface, a peak appears at a 2θ of around 56°. This peak is attributed to the (110) plane of the InGaZnO₄ crystal. When analysis (φ scan) is performed with 2θ fixed at around 56° and with the sample rotated using a normal vector to the sample surface as an axis (φ axis), as shown in FIG. 9B, a peak is not clearly observed. In contrast, in the case where single crystal InGaZnO₄ is subjected to φ scan with 2θ fixed at around 56°, as shown in FIG. 9C, six peaks that are derived from crystal planes equivalent to the (110) plane are observed. Accordingly, the structural analysis using XRD shows that the directions of a-axes and b-axes are irregularly oriented in the CAAC-OS.

Next, a CAAC-OS analyzed by electron diffraction is described. For example, when an electron beam with a probe diameter of 300 nm is incident on a CAAC-OS including an InGaZnO₄ crystal in a direction parallel to the formation surface of the CAAC-OS, a diffraction pattern (also referred to as a selected-area electron diffraction pattern) shown in FIG. 9D can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 9E shows a diffraction pattern obtained in such a manner that an electron beam with a probe diameter of 300 nm is incident on the same sample in a direction perpendicular to the sample surface. As shown in FIG. 9E, a ring-like diffraction pattern is observed. Thus, the electron diffraction using an electron beam with a probe diameter of 300 nm also indicates that the a-axes and b-axes of the pellets included in the CAAC-OS do not have regular orientation. The first ring in FIG. 9E is considered to be derived from the (010) plane, the (100) plane, and the like of the InGaZnO₄ crystal. The second ring in FIG. 9E is considered to be derived from the (110) plane and the like.

In a combined analysis image (also referred to as a high-resolution TEM image) of a bright-field image and a diffraction pattern of a CAAC-OS, which is obtained using a transmission electron microscope (TEM), a plurality of pellets can be observed. However, even in the high-resolution TEM image, a boundary between pellets, that is, a grain boundary is not clearly observed in some cases. Thus, in the CAAC-OS, a reduction in electron mobility due to the grain boundary is less likely to occur.

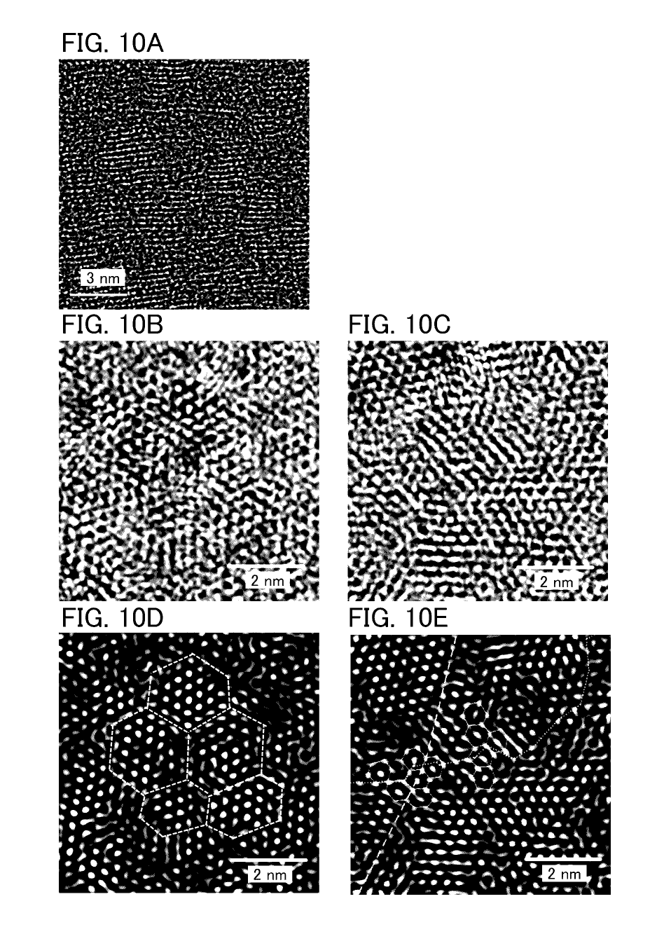

FIG. 10A shows a high-resolution TEM image of a cross section of the CAAC-OS that is observed from a direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be observed with, for example, an atomic resolution analytical electron microscope JEM-ARM200F manufactured by JEOL Ltd.

FIG. 10A shows pellets in which metal atoms are arranged in a layered manner. FIG. 10A proves that the size of a pellet is greater than or equal to 1 nm or greater than or equal to 3 nm. Therefore, the pellet can also be referred to as a nanocrystal (nc). Furthermore, the CAAC-OS can also be referred to as an oxide semiconductor including c-axis aligned nanocrystals (CANC). A pellet reflects unevenness of a formation surface or a top surface of the CAAC-OS, and is parallel to the formation surface or the top surface of the CAAC-OS.

FIGS. 10B and 10C show Cs-corrected high-resolution TEM images of a plane of the CAAC-OS observed from a direction substantially perpendicular to the sample surface. FIGS. 10D and 10E are images obtained through image processing of FIGS. 10B and 10C. The method of image processing is as follows. The image in FIG. 10B is subjected to fast Fourier transform (FFT), so that an FFT image is obtained. Then, mask processing is performed such that a range of from 2.8 nm⁻¹ to 5.0 nm⁻¹ from the origin point in the obtained FFT image remains. After the mask processing, the FFT image is processed by inverse fast Fourier transform (IFFT) to obtain a processed image. The image obtained in this manner is called an FFT filtering image. The FFT filtering image is a Cs-corrected high-resolution TEM image from which a periodic component is extracted, and shows a lattice arrangement.

In FIG. 10D, a portion where a lattice arrangement is broken is denoted with a dashed line. A region surrounded by a dashed line is one pellet. The portion denoted with the dashed line is a junction of pellets. The dashed line draws a hexagon, which means that the pellet has a hexagonal shape. Note that the shape of the pellet is not always a regular hexagon but is a non-regular hexagon in many cases.

In FIG. 10E, a dotted line denotes a portion where the direction of a lattice arrangement is changed between a region with a regular lattice arrangement and another region with a regular lattice arrangement, and a dashed line denotes the change in the direction of the lattice arrangement. A clear crystal grain boundary cannot be observed even in the vicinity of the dotted line. When a lattice point in the vicinity of the dotted line is regarded as a center and surrounding lattice points are joined, a distorted hexagon, pentagon, and/or heptagon can be formed. That is, a lattice arrangement is distorted so that formation of a crystal grain boundary is inhibited. This is probably because the CAAC-OS can tolerate distortion owing to a low density of the atomic arrangement in an a-b plane direction, the interatomic bond distance changed by substitution of a metal element, and the like.

As described above, the CAAC-OS has c-axis alignment, its pellets (nanocrystals) are connected in an a-b plane direction, and the crystal structure has distortion. For this reason, the CAAC-OS can also be referred to as an oxide semiconductor including a c-axis-aligned a-b-plane-anchored (CAA) crystal.

The CAAC-OS is an oxide semiconductor with high crystallinity. Entry of impurities, formation of defects, or the like might decrease the crystallinity of an oxide semiconductor. This means that the CAAC-OS has small amounts of impurities and defects (e.g., oxygen vacancies).

Note that the impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

The characteristics of an oxide semiconductor having impurities or defects might be changed by light, heat, or the like. Impurities included in the oxide semiconductor might serve as carrier traps or carrier generation sources, for example. For example, oxygen vacancies in the oxide semiconductor might serve as carrier traps or serve as carrier generation sources when hydrogen is captured therein.

The CAAC-OS having small amounts of impurities and oxygen vacancies is an oxide semiconductor film with a low carrier density (specifically, lower than 8×10¹¹/cm³, preferably lower than 1×10¹¹/cm³, and further preferably lower than 1×10¹⁰/cm³ and higher than or equal to 1×10⁻⁹/cm³). Such an oxide semiconductor is referred to as a highly purified intrinsic or substantially highly purified intrinsic oxide semiconductor. A CAAC-OS has a low impurity concentration and a low density of defect states. Thus, the CAAC-OS can be referred to as an oxide semiconductor having stable characteristics.

<nc-OS>

Next, an nc-OS is described.

Analysis of an nc-OS by XRD is described. When the structure of an nc-OS is analyzed by an out-of-plane method, a peak indicating orientation does not appear. That is, a crystal of an nc-OS does not have orientation.

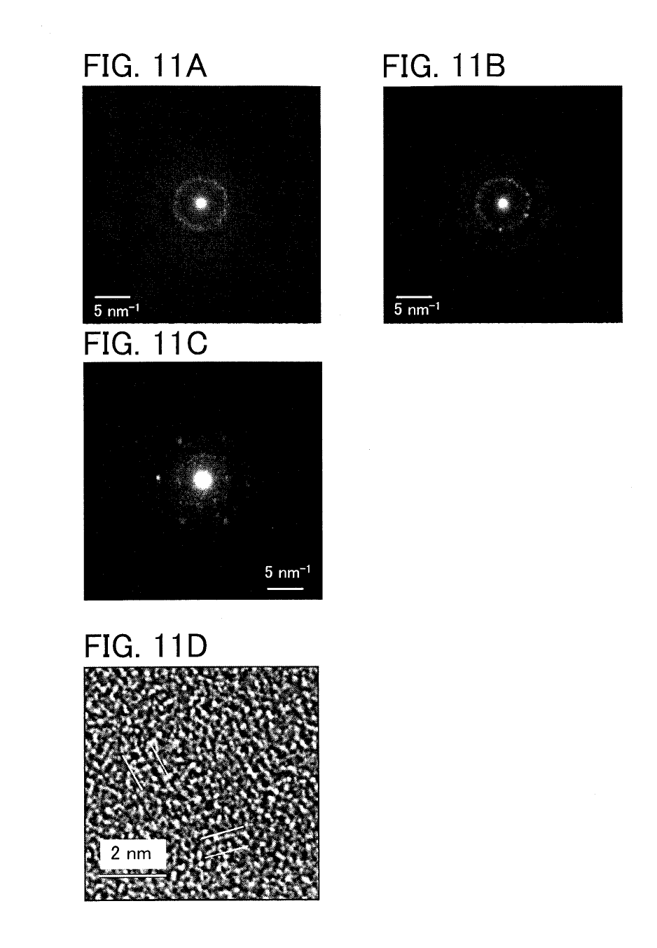

For example, when an electron beam with a probe diameter of 50 nm is incident on a 34-nm-thick region of thinned nc-OS including an InGaZnO₄ crystal in a direction parallel to the formation surface, a ring-shaped diffraction pattern (a nanobeam electron diffraction pattern) shown in FIG. 11A is observed. FIG. 11B shows a diffraction pattern obtained when an electron beam with a probe diameter of 1 nm is incident on the same sample. As shown in FIG. 11B, a plurality of spots are observed in a ring-like region. In other words, ordering in an nc-OS is not observed with an electron beam with a probe diameter of 50 nm but is observed with an electron beam with a probe diameter of 1 nm.

Furthermore, an electron diffraction pattern in which spots are arranged in an approximately hexagonal shape is observed in some cases as shown in FIG. 11C when an electron beam having a probe diameter of 1 nm is incident on a region with a thickness of less than 10 nm. This means that an nc-OS has a well-ordered region, i.e., a crystal, in the range of less than 10 nm in thickness. Note that an electron diffraction pattern having regularity is not observed in some regions because crystals are aligned in various directions.

FIG. 11D shows a Cs-corrected high-resolution TEM image of a cross section of an nc-OS observed from the direction substantially parallel to the formation surface. In a high-resolution TEM image, an nc-OS has a region in which a crystal part is observed, such as the part indicated by additional lines in FIG. 11D, and a region in which a crystal part is not clearly observed. In most cases, the size of a crystal part included in the nc-OS is greater than or equal to 1 nm and less than or equal to 10 nm, or specifically, greater than or equal to 1 nm and less than or equal to 3 nm. Note that an oxide semiconductor including a crystal part whose size is greater than 10 nm and less than or equal to 100 nm is sometimes referred to as a microcrystalline oxide semiconductor. In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

As described above, in the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not ordered. Accordingly, the nc-OS cannot be distinguished from an a-like OS or an amorphous oxide semiconductor, depending on an analysis method.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

The nc-OS is an oxide semiconductor that has high regularity as compared with an amorphous oxide semiconductor. Therefore, the nc-OS is likely to have a lower density of defect states than an a-like OS and an amorphous oxide semiconductor. Note that there is no regularity of crystal orientation between different pellets in the nc-OS. Therefore, the nc-OS has a higher density of defect states than the CAAC-OS.

<a-like OS>

An a-like OS has a structure between those of the nc-OS and the amorphous oxide semiconductor.

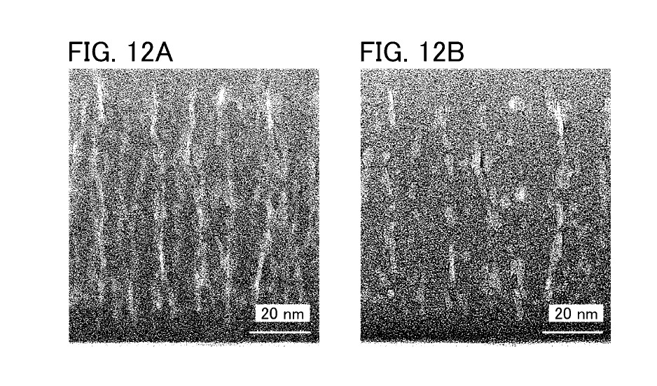

FIGS. 12A and 12B are high-resolution cross-sectional TEM images of an a-like OS. FIG. 12A is the high-resolution cross-sectional TEM image of the a-like OS at the start of the electron irradiation. FIG. 12B is the high-resolution cross-sectional TEM image of a-like OS after the electron (e) irradiation at 4.3×10⁸ e⁻/nm². FIGS. 12A and 12B show that stripe-like bright regions extending vertically are observed in the a-like OS from the start of the electron irradiation. It can be also found that the shape of the bright region changes after the electron irradiation. Note that the bright region is presumably a void or a low-density region.

The a-like OS has an unstable structure because it contains a void. To verify that an a-like OS has an unstable structure as compared with a CAAC-OS and an nc-OS, a change in structure caused by electron irradiation is described below.

An a-like OS, an nc-OS, and a CAAC-OS are prepared as samples. Each of the samples is an In—Ga—Zn oxide.

First, a high-resolution cross-sectional TEM image of each sample is obtained. The high-resolution cross-sectional TEM images show that all the samples have crystal parts.

It is known that a unit cell of an InGaZnO₄ crystal has a structure in which nine layers including three In—O layers and six Ga—Zn—O layers are stacked in the c-axis direction. The distance between the adjacent layers is equivalent to the lattice spacing on the (009) plane (also referred to as d value). The value is calculated to be 0.29 nm from crystal structural analysis. Accordingly, a portion where the spacing between lattice fringes is greater than or equal to 0.28 nm and less than or equal to 0.30 nm is regarded as a crystal part of InGaZnO₄ in the following description. Each of lattice fringes corresponds to the a-b plane of the InGaZnO₄ crystal.

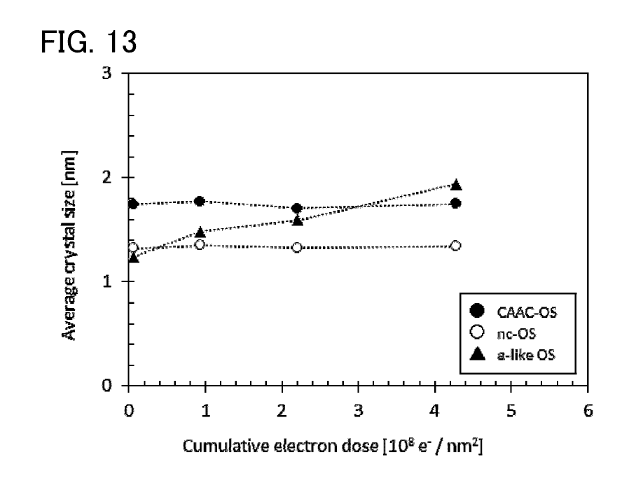

FIG. 13 shows a change in the average size of crystal parts (at 22 points to 30 points) in each sample. Note that the crystal part size corresponds to the length of a lattice fringe. FIG. 13 indicates that the crystal part size in the a-like OS increases with an increase in the cumulative electron dose in obtaining TEM images, for example. As shown in FIG. 13, a crystal part of approximately 1.2 nm (also referred to as an initial nucleus) at the start of TEM observation grows to a size of approximately 1.9 nm at a cumulative electron (e⁻) dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm². As shown in FIG. 13, the crystal part sizes in an nc-OS and a CAAC-OS are approximately 1.3 nm and approximately 1.8 nm, respectively, regardless of the cumulative electron dose. For the electron beam irradiation and TEM observation, a Hitachi H-9000NAR transmission electron microscope was used. The conditions of electron beam irradiation were as follows: the accelerating voltage was 300 kV; the current density was 6.7×10⁵ e⁻/(nm²·s); and the diameter of irradiation region was 230 nm.

In this manner, growth of the crystal part in the a-like OS is sometimes induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has a lower density than the nc-OS and the CAAC-OS because it contains a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. Note that it is difficult to form an oxide semiconductor having a density of lower than 78% of the density of the single crystal oxide semiconductor.

For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that in the case where an oxide semiconductor having a certain composition does not exist in a single crystal structure, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be calculated using a weighted average according to the combination ratio of the single crystal oxide semiconductors with different compositions. Note that it is preferable to use as few kinds of single crystal oxide semiconductors as possible to calculate the density.

As described above, oxide semiconductors have various structures and various properties. Note that an oxide semiconductor may be a stacked layer including two or more films of an amorphous oxide semiconductor, an a-like OS, an nc-OS, and a CAAC-OS, for example.

### <Transistor 1>

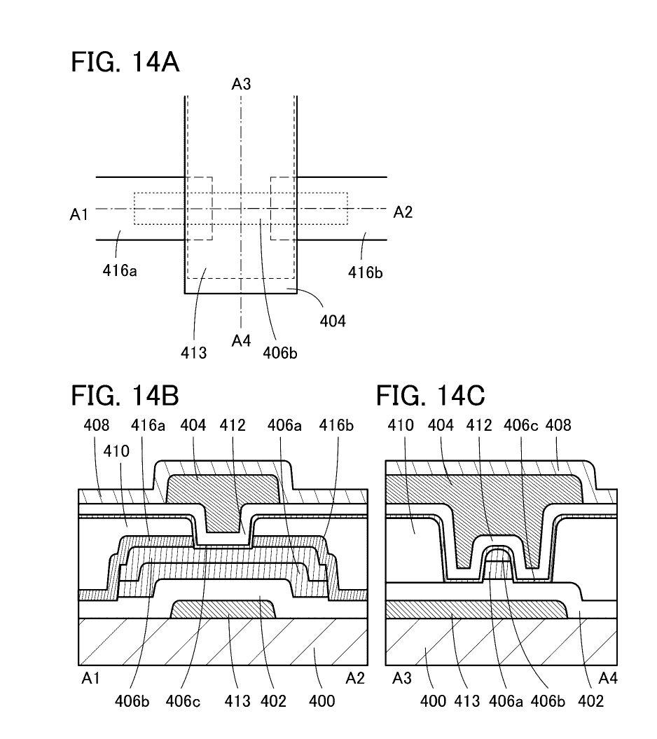

FIGS. 14A to 14C are a top view and cross-sectional views illustrating a transistor of one embodiment of the present invention. FIG. 14A is a top view, and FIGS. 14B and 14C are cross-sectional views taken along dashed-dotted lines A1-A2 and A3-A4 in FIG. 14A, respectively. Note that for simplification of the drawing, some components are not illustrated in the top view in FIG. 14A.

The transistor illustrated in FIGS. 14A to 14C includes a conductor 413 over a substrate 400, an insulator 402 over the substrate 400 and the conductor 413, an insulator 406a over the insulator 402, a semiconductor 406b over the insulator 406a, a conductor 416a and a conductor 416b which are arranged to be separated from each other while being in contact with top and side surfaces of the semiconductor 406b, an insulator 410 over the conductor 416a and the conductor 416b, an insulator 406c over the semiconductor 406b and the insulator 410, an insulator 412 over the insulator 406c, a conductor 404 over the insulator 412, and an insulator 408 over the conductor 404. Although the conductor 413 is part of the transistor in this non-limiting example, the conductor 413 may be a component independent of the transistor, for example. Furthermore, the transistor does not necessarily include one or more of the insulator 408 and the insulator 410.

In the cross-sectional views shown in FIGS. 14B and 14C, a top surface of the insulator 410 is parallel to a rear surface of the substrate 400; however, it is not necessary that they are parallel to each other. For example, the top surface of the insulator 410 may have a shape along unevenness of the conductor 416a and the conductor 416b.

The conductor 404 includes a region that faces the top surface and the side surface of the semiconductor 406b with the insulator 412 provided therebetween in the cross section taken along line A3-A4. The conductor 413 includes a region which faces the bottom surface of the semiconductor 406b with the insulator 402 provided therebetween.

The semiconductor 406b serves as a channel formation region of the transistor. The conductor 404 serves as a first gate electrode (also referred to as a front gate electrode) of the transistor. The conductor 413 serves as a second gate electrode (also referred to as a back gate electrode) of the transistor. The conductor 416a and the conductor 416b serve as a source electrode and a drain electrode of the transistor.

As illustrated in FIG. 14C, the semiconductor 406b can be electrically surrounded by an electric field of the conductor 404 and/or the conductor 413 (a structure in which a semiconductor is electrically surrounded by an electric field of a conductor is referred to as a surrounded channel (s-channel) structure). Therefore, a channel is formed in the entire semiconductor 406b (the top, bottom, and side surfaces). In the s-channel structure, a large amount of current can flow between a source and a drain of the transistor, so that a high on-state current can be achieved.

In the case where the transistor has the s-channel structure, a channel is formed also in the side surface of the semiconductor 406b. Therefore, as the semiconductor 406b has a larger thickness, the channel formation region becomes larger. In other words, the thicker the semiconductor 406b is, the larger the on-state current of the transistor is. In addition, when the semiconductor 406b is thicker, the proportion of the region with a high carrier controllability increases, leading to a smaller subthreshold swing value. For example, the semiconductor 406b has a region with a thickness of greater than or equal to 10 nm, preferably greater than or equal to 20 nm, further preferably greater than or equal to 40 nm, still further preferably greater than or equal to 60 nm, and yet still further preferably greater than or equal to 100 nm. In addition, to prevent a decrease in the productivity of the semiconductor device, the semiconductor 406b has a region with a thickness of, for example, less than or equal to 300 nm, preferably less than or equal to 200 nm, and further preferably less than or equal to 150 nm. In some cases, when the channel formation region is reduced in size, the electrical characteristics of the transistor with a smaller thickness of the semiconductor 406b may be improved. Therefore, the semiconductor 406b may have a thickness less than 10 nm.

The s-channel structure is suitable for a miniaturized transistor because a high on-state current can be achieved. A semiconductor device including the miniaturized transistor can have a high integration degree and high density. For example, the transistor includes a region having a channel length of preferably less than or equal to 40 nm, further preferably less than or equal to 30 nm, and still further preferably less than or equal to 20 nm and a region having a channel width of preferably less than or equal to 40 nm, further preferably less than or equal to 30 nm, and still further preferably less than or equal to 20 nm.

As the substrate 400, an insulator substrate, a semiconductor substrate, or a conductor substrate may be used, for example. As the insulator substrate, a glass substrate, a quartz substrate, a sapphire substrate, a stabilized zirconia substrate (e.g., an yttria-stabilized zirconia substrate), or a resin substrate is used, for example. As the semiconductor substrate, a single material semiconductor substrate of silicon, germanium, or the like or a compound semiconductor substrate whose material is silicon carbide, silicon germanium, gallium arsenide, indium phosphide, zinc oxide, gallium oxide, or the like is used, for example. A semiconductor substrate in which an insulator region is provided in the above semiconductor substrate, e.g., a silicon on insulator (SOI) substrate or the like is used. As the conductor substrate, a graphite substrate, a metal substrate, an alloy substrate, a conductive resin substrate, or the like is used. A substrate including a metal nitride, a substrate including a metal oxide, or the like is used. An insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. As the element provided over the substrate, a capacitor, a resistor, a switching element, a light-emitting element, a memory element, or the like is used.

Alternatively, a flexible substrate may be used as the substrate 400. As a method for providing a device over a flexible substrate, there is a method in which the device is formed over a non-flexible substrate and then the device is separated and transferred to the substrate 400 which is a flexible substrate. In that case, a separation layer is preferably provided between the non-flexible substrate and the device. As the substrate 400, a sheet, a film, or a foil containing a fiber may be used. The substrate 400 may have elasticity. The substrate 400 may have a property of returning to its original shape when bending or pulling is stopped. Alternatively, the substrate 400 may have a property of not returning to its original shape. The thickness of the substrate 400 is, for example, greater than or equal to 5 μm and less than or equal to 700 μm, preferably greater than or equal to 10 μm and less than or equal to 500 μm, and further preferably greater than or equal to 15 μm and less than or equal to 300 μm. When the substrate 400 has a small thickness, the weight of the semiconductor device can be reduced. When the substrate 400 has a small thickness, even in the case of using glass or the like, the substrate 400 may have elasticity or a property of returning to its original shape when bending or pulling is stopped. Therefore, an impact applied to the semiconductor device over the substrate 400, which is caused by dropping or the like, can be reduced. That is, a durable semiconductor device can be provided.

For the substrate 400 which is a flexible substrate, metal, an alloy, resin, glass, or fiber thereof can be used, for example. The flexible substrate 400 preferably has a lower coefficient of linear expansion because deformation due to an environment is suppressed. The flexible substrate 400 is formed using, for example, a material whose coefficient of linear expansion is lower than or equal to 1×10⁻³/K, lower than or equal to 5×10⁻⁵/K, or lower than or equal to 1×10⁻⁵/K. Examples of the resin include polyester, polyolefin, polyamide (e.g., nylon or aramid), polyimide, polycarbonate, and acrylic. In particular, aramid is preferably used for the flexible substrate 400 because of its low coefficient of linear expansion.

The conductor 413 may be formed to have a single-layer structure or a stacked-layer structure using a conductor containing, for example, one or more of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound of the above element may be used, for example, and an alloy containing aluminum, an alloy containing copper and titanium, an alloy containing copper and manganese, a compound containing indium, tin, and oxygen, a compound containing titanium and nitrogen, or the like may be used.

The insulator 402 may be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 402 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulator 402 preferably contains excess oxygen in the case where the semiconductor 406b is an oxide semiconductor. Note that excess oxygen means oxygen in an insulator or the like which does not bond with (which is liberated from) the insulator or the like or has low bonding energy with the insulator or the like.

Here, an insulator including excess oxygen may release oxygen, the amount of which is higher than or equal to 1×10¹⁸ atoms/cm³, higher than or equal to 1×10¹⁹ atoms/cm³, or higher than or equal to 1×10²⁰ atoms/cm³ (converted into the number of oxygen atoms) in thermal desorption spectroscopy (TDS) analysis in the range of a surface temperature of 100° C. to 700° C. or 100° C. to 500° C.

The method of measuring the amount of released oxygen using TDS analysis is described below.

The total amount of released gas from a measurement sample in TDS analysis is proportional to the integral value of the ion intensity of the released gas. Then, comparison with a reference sample is made, whereby the total amount of released gas can be calculated.

For example, the number of released oxygen molecules (N_{O2}) from a measurement sample can be calculated according to the following formula using the TDS results of a silicon substrate containing hydrogen at a predetermined density, which is a reference sample, and the TDS results of the measurement sample. Here, all gases having a mass-to-charge ratio of 32 which are obtained in the TDS analysis are assumed to originate from an oxygen molecule. Note that CH₃OH, which is a gas having a mass-to-charge ratio of 32, is not taken into consideration because it is unlikely to be present. Furthermore, an oxygen molecule including an oxygen atom having a mass number of 17 or 18 which is an isotope of an oxygen atom is also not taken into consideration because the proportion of such a molecule in the natural world is minimal.

N_{O2}═N_{H2}/S_{H2}×S_{O2}×α

The value N_{H2} is obtained by conversion of the number of hydrogen molecules desorbed from the reference sample into densities. The value S_{H2} is the integral value of ion intensity in the case where the reference sample is subjected to the TDS analysis. Here, the reference value of the reference sample is set to N_{H2}/S_{H2}. The value S_{O2} is the integral value of ion intensity when the measurement sample is analyzed by TDS. The value a is a coefficient affecting the ion intensity in the TDS analysis. Refer to Japanese Published Patent Application No. H6-275697 for details of the above formula. The amount of released oxygen was measured with a thermal desorption spectroscopy apparatus produced by ESCO Ltd., EMD-WA1000S/W using a silicon substrate containing a certain amount of hydrogen atoms as the reference sample.

Furthermore, in the TDS analysis, oxygen is partly detected as an oxygen atom. The ratio between oxygen molecules and oxygen atoms can be calculated from the ionization rate of the oxygen molecules. Note that, since the above α includes the ionization rate of the oxygen molecules, the number of the released oxygen atoms can also be estimated through the evaluation of the number of the released oxygen molecules.

Note that N_{O2} is the number of the released oxygen molecules. The number of released oxygen in the case of being converted into oxygen atoms is twice the number of the released oxygen molecules.

Furthermore, the insulator from which oxygen is released by heat treatment may contain a peroxide radical. Specifically, the spin density of a signal attributed to the peroxide radical is greater than or equal to 5×10¹⁷ spins/cm³. Note that the insulator containing a peroxide radical may have an asymmetric signal with a g factor of approximately 2.01 in electron spin resonance (ESR).

The conductor 416a and the conductor 416b may be formed to have a single-layer structure or a stacked-layer structure including a conductor containing, for example, one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound of the above element may be used, for example, and an alloy containing aluminum, an alloy containing copper and titanium, an alloy containing copper and manganese, a compound containing indium, tin, and oxygen, a compound containing titanium and nitrogen, or the like may be used.

The insulator 410 may be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 410 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

Note that the insulator 410 preferably includes an insulator with low relative permittivity. For example, the insulator 410 preferably includes silicon oxide, silicon oxynitride, silicon nitride oxide, silicon nitride, resin, or the like. Examples of the resin include polyester, polyolefin, polyamide (e.g., nylon or aramid), polyimide, polycarbonate, and acrylic.

The insulator 412 may be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 402 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulator 412 preferably contains excess oxygen in the case where the semiconductor 406b is an oxide semiconductor.

The conductor 404 may be formed to have a single-layer structure or a stacked-layer structure using a conductor containing, for example, one or more of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound of the above element may be used, for example, and an alloy containing aluminum, an alloy containing copper and titanium, an alloy containing copper and manganese, a compound containing indium, tin, and oxygen, a compound containing titanium and nitrogen, or the like may be used.

The insulator 408 is, for example, an insulator having a low hydrogen-transmitting property (i.e., a hydrogen barrier property).

Because of its small atomic radius or the like, hydrogen is likely to be diffused into an insulator (i.e., the diffusion coefficient of hydrogen is large). For example, a low-density insulator has a high hydrogen-transmitting property. In other words, a high-density insulator has a low hydrogen-transmitting property. The density of a low-density insulator is not always low throughout the insulator; an insulator including a low-density part is also referred to as a low-density insulator. This is because the low-density part serves as a hydrogen path. Although a density that allows hydrogen to be transmitted is not limited, it is typically lower than 2.6 g/cm³. Examples of a low-density insulator include an inorganic insulator such as silicon oxide or silicon oxynitride and an organic insulator such as polyester, polyolefin, polyamide (e.g., nylon or aramid), polyimide, polycarbonate, or acrylic. Examples of a high-density insulator include magnesium oxide, aluminum oxide, germanium oxide, gallium oxide, yttrium oxide, zirconium oxide, lanthanum oxide, neodymium oxide, hafnium oxide, and tantalum oxide. Note that a low-density insulator and a high-density insulator are not limited to these insulators. For example, the insulators may contain one or more elements selected from boron, nitrogen, fluorine, neon, phosphorus, chlorine, and argon.

An insulator having crystal grain boundaries can have a high hydrogen-transmitting property. In other words, hydrogen is less likely transmitted through an insulator having no grain boundaries or few grain boundaries. For example, a non-polycrystalline insulator (e.g., an amorphous insulator) has a lower hydrogen-transmitting property than a polycrystalline insulator.

An insulator having a high hydrogen-bonding energy has a low hydrogen-transmitting property in some cases. For example, when an insulator which forms a hydrogen compound by bonding with hydrogen has bonding energy at which hydrogen is not released at temperatures in fabrication and operation of a device, the insulator can be in the category of an insulator having a low hydrogen-transmitting property. For example, an insulator which forms a hydrogen compound at higher than or equal to 200° C. and lower than or equal to 1000° C., higher than or equal to 300° C. and lower than or equal to 1000° C., or higher than or equal to 400° C. and lower than or equal to 1000° C. has a low hydrogen-transmitting property in some cases. An insulator which forms a hydrogen compound and which releases hydrogen at higher than or equal to 200° C. and lower than or equal to 1000° C., higher than or equal to 300° C. and lower than or equal to 1000° C., or higher than or equal to 400° C. and lower than or equal to 1000° C. has a low hydrogen-transmitting property in some cases. An insulator which forms a hydrogen compound and which releases hydrogen at higher than or equal to 20° C. and lower than or equal to 400° C., higher than or equal to 20° C. and lower than or equal to 300° C., or higher than or equal to 20° C. and lower than or equal to 200° C. has a high hydrogen-transmitting property in some cases. Hydrogen which is released easily and liberated can be referred to as excess hydrogen.

The insulator 408 is, for example, an insulator having a low oxygen-transmitting property (i.e., an oxygen barrier property).

The insulator 408 is, for example, an insulator having a low water-transmitting property (i.e., a water barrier property).

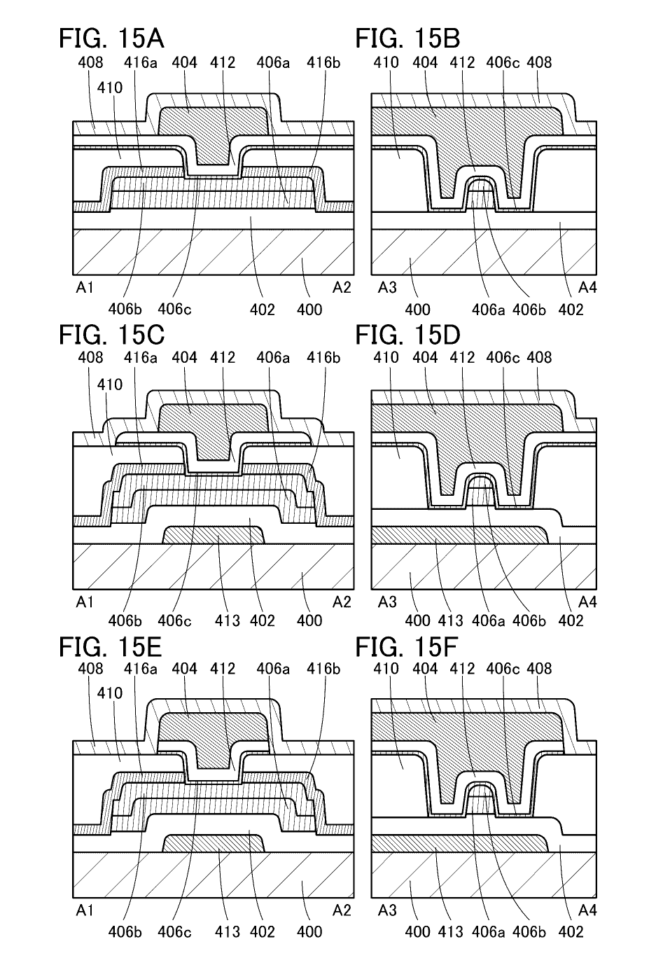

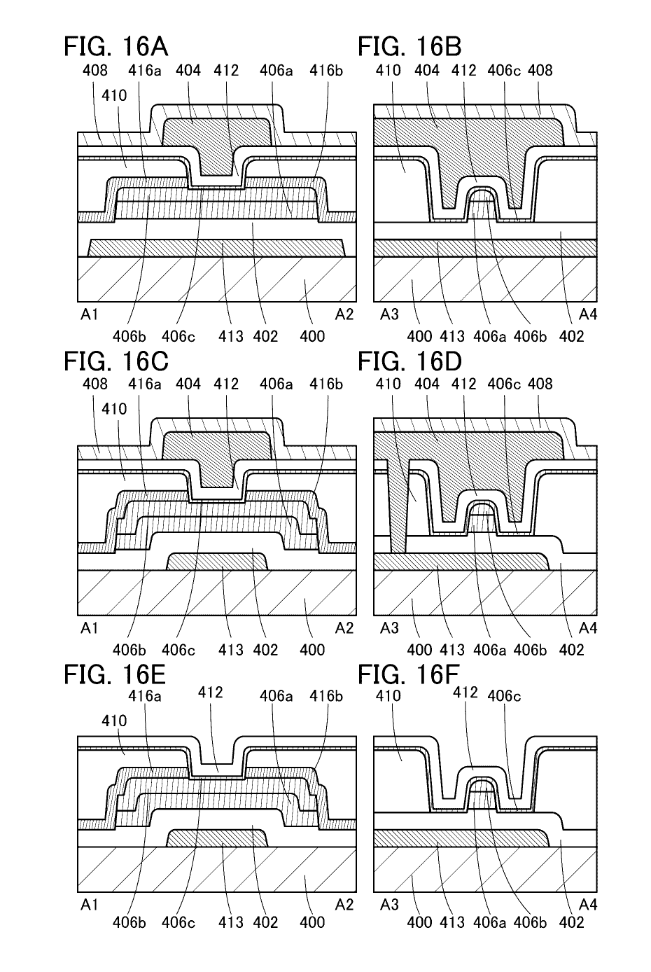

Note that the conductor 413 is not necessarily formed (see FIGS. 15A and 15B). A shape in which the insulator 412 and the insulator 406c protrude from the conductor 404 may be employed (see FIGS. 15C and 15D). A shape in which the insulator 412 and the insulator 406c do not protrude from the conductor 404 may be employed (see FIGS. 15E and 15F). In the A1-A2 cross section, the width of the conductor 413 may be larger than that of the semiconductor 406b (see FIGS. 16A and 16B). The conductor 413 may be in contact with the conductor 404 through an opening (see FIGS. 16C and 16D). The conductor 404 is not necessarily formed (see FIGS. 16E and 16F).

The insulator 406a, the semiconductor 406b, and the insulator 406c will be described.

Placing the insulator 406a under the semiconductor 406b and placing the insulator 406c over the semiconductor 406b can increase electrical characteristics of the transistor in some cases.

The insulator 406a, the semiconductor 406b, and the insulator 406c preferably include a CAAC-OS.

The semiconductor 406b is an oxide containing indium, for example. The oxide semiconductor 406b can have high carrier mobility (electron mobility) by containing indium, for example. The semiconductor 406b preferably contains an element M. The element M is preferably aluminum, gallium, yttrium, tin, or the like. Other elements which can be used as the element M are boron, silicon, titanium, iron, nickel, germanium, zirconium, molybdenum, lanthanum, cerium, neodymium, hafnium, tantalum, tungsten, magnesium, and the like. Note that two or more of the above elements may be used in combination as the element M. The element M is an element having high bonding energy with oxygen, for example. The element M is an element whose bonding energy with oxygen is higher than that of indium. The element M is an element that can increase the energy gap of the oxide, for example. Furthermore, the semiconductor 406b preferably contains zinc. When the oxide contains zinc, the oxide semiconductor is easily crystallized, in some cases.

Note that the semiconductor 406b is not limited to the oxide containing indium. The semiconductor 406b may be, for example, an oxide which does not contain indium and contains zinc, an oxide which does not contain indium and contains gallium, or an oxide which does not contain indium and contains tin, e.g., a zinc tin oxide or a gallium tin oxide.

For the semiconductor 406b, an oxide with a wide energy gap may be used, for example. For example, the energy gap of the semiconductor 406b is greater than or equal to 2.5 eV and less than or equal to 4.2 eV, preferably greater than or equal to 2.8 eV and less than or equal to 3.8 eV, and further preferably greater than or equal to 3 eV and less than or equal to 3.5 eV.

For example, the insulator 406a and the insulator 406c are oxides including one or more elements, or two or more elements other than oxygen included in the semiconductor 406b. Since the insulator 406a and the insulator 406c each include one or more elements, or two or more elements other than oxygen included in the semiconductor 406b, a defect state is less likely to be formed at the interface between the insulator 406a and the semiconductor 406b and the interface between the semiconductor 406b and the insulator 406c.

The insulator 406a, the semiconductor 406b, and the insulator 406c preferably include at least indium. In the case of using an In-M-Zn oxide as the insulator 406a, when the summation of In and M is assumed to be 100 atomic %, the proportions of In and M are preferably set to be less than 50 atomic % and greater than 50 atomic %, respectively, further preferably less than 25 atomic % and greater than 75 atomic %, respectively. In the case of using an In-M-Zn oxide as the semiconductor 406b, when the summation of In and M is assumed to be 100 atomic %, the proportions of In and M are preferably set to be greater than 25 atomic % and less than 75 atomic %, respectively, and further preferably greater than 34 atomic % and less than 66 atomic %, respectively. In the case of using an In-M-Zn oxide as the insulator 406c, when the summation of In and M is assumed to be 100 atomic %, the proportions of In and M are preferably set to be less than 50 atomic % and greater than 50 atomic %, respectively, and further preferably less than 25 atomic % and greater than 75 atomic %, respectively. Note that the insulator 406c may be an oxide that is of the same type as the oxide of the insulator 406a. Note that the insulator 406a and/or the insulator 406c do/does not necessarily contain indium in some cases. For example, the insulator 406a and/or the insulator 406c may be gallium oxide. Note that the atomic ratios of the elements included in the insulator 406a, the semiconductor 406b, and the insulator 406c are not necessarily simple ratios of integers.

As the semiconductor 406b, an oxide having an electron affinity higher than those of the insulators 406a and 406c is used. For example, as the semiconductor 406b, an oxide having an electron affinity higher than those of the insulators 406a and 406c by 0.07 eV or higher and 1.3 eV or lower, preferably 0.1 eV or higher and 0.7 eV or lower, further preferably 0.15 eV or higher and 0.4 eV or lower is used. Note that the electron affinity refers to an energy difference between the vacuum level and the conduction band minimum.

An indium gallium oxide has small electron affinity and a high oxygen-blocking property. Therefore, the insulator 406c preferably includes an indium gallium oxide. The fraction of gallium atoms [Ga/(In+Ga)] is, for example, higher than or equal to 70%, preferably higher than or equal to 80%, further preferably higher than or equal to 90%.

At this time, when gate voltage is applied, a channel is formed in the semiconductor 406b whose electron affinity is the highest among the insulator 406a, the semiconductor 406b, and the insulator 406c.

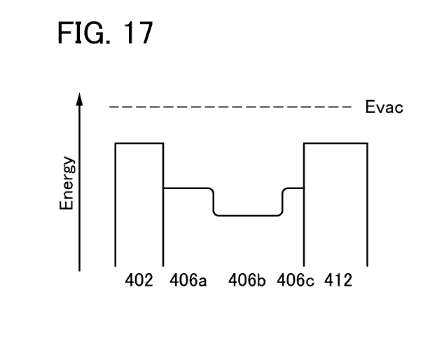

In some cases, there is a mixed region of the insulator 406a and the semiconductor 406b between the insulator 406a and the semiconductor 406b. Furthermore, in some cases, there is a mixed region of the semiconductor 406b and the insulator 406c between the semiconductor 406b and the insulator 406c. The mixed region has a low density of defect states. For that reason, in a band diagram of a stack including the insulator 406a, the semiconductor 406b, and the insulator 406c (see FIG. 17), energy changes continuously at each interface and in the vicinity of the interface (continuous junction). Note that boundaries of the insulator 406a, the semiconductor 406b, and the insulator 406c are not clear in some cases.

At this time, electrons move mainly in the semiconductor 406b, not in the insulator 406a and the insulator 406c. Note that the insulator 406a and the insulator 406c can exhibit a property of any of a conductor, a semiconductor, and an insulator when existing alone. When the transistor operates, however, they each have a region where a channel is not formed. Specifically, a channel is formed only in a region near the interface between the insulator 406a and the semiconductor 406b and a region near the interface between the insulator 406c and the semiconductor 406b, whereas a channel is not formed in the other region. Therefore, the insulator 406a and the insulator 406c can be called insulators when the transistor operates, and are thus referred to as, not semiconductors or conductors, but insulators in this specification. The insulator 406a, the semiconductor 406b, and the insulator 406c are separately called semiconductor or insulator only because of the relative difference in physical property. Therefore, for example, an insulator that can be used as the insulator 406a or the insulator 406c can be used as the semiconductor 406b in some cases. As described above, when the density of defect states at the interface between the insulator 406a and the semiconductor 406b and the density of defect states at the interface between the semiconductor 406b and the insulator 406c are decreased, electron movement in the semiconductor 406b is less likely to be inhibited and the on-state current of the transistor can be increased.

As factors of inhibiting electron movement are decreased, the on-state current of the transistor can be increased. For example, in the case where there is no factor of inhibiting electron movement, electrons are assumed to be efficiently moved. Electron movement is inhibited, for example, in the case where physical unevenness of the channel formation region is large.

To increase the on-state current of the transistor, for example, root mean square (RMS) roughness with a measurement area of 1 μm×1 μm of the top surface or the bottom surface of the semiconductor 406b (a formation surface; here, a top surface of the insulator 406a) is less than 1 nm, preferably less than 0.6 nm, further preferably less than 0.5 nm, still further preferably less than 0.4 nm. The average surface roughness (also referred to as Ra) with the measurement area of 1 μm×1 μm is less than 1 nm, preferably less than 0.6 nm, further preferably less than 0.5 nm, still further preferably less than 0.4 nm. The maximum difference (P−V) with the measurement area of 1 μm×1 μm is less than 10 nm, preferably less than 9 nm, further preferably less than 8 nm, still further preferably less than 7 nm. RMS roughness, Ra, and P−V can be measured using a scanning probe microscope SPA-500 manufactured by SII Nano Technology Inc.

Moreover, the thickness of the insulator 406c is preferably as small as possible to increase the on-state current of the transistor. For example, the insulator 406c is formed to include a region with a thickness of less than 10 nm, preferably less than or equal to 5 nm, further preferably less than or equal to 3 nm. Meanwhile, the insulator 406c has a function of blocking entry of elements other than oxygen (such as hydrogen and silicon) included in the adjacent insulator into the semiconductor 406b where a channel is formed. For this reason, it is preferable that the insulator 406c have a certain thickness. For example, the insulator 406c is formed to include a region with a thickness of greater than or equal to 0.3 nm, preferably greater than or equal to 1 nm, and further preferably greater than or equal to 2 nm. The insulator 406c preferably has an oxygen blocking property to suppress outward diffusion of oxygen released from the insulator 402 and the like.

To improve reliability, preferably, the thickness of the insulator 406a is large and the thickness of the insulator 406c is small. For example, the insulator 406a includes a region with a thickness of, for example, greater than or equal to 10 nm, preferably greater than or equal to 20 nm, further preferably greater than or equal to 40 nm, and still further preferably greater than or equal to 60 nm. When the thickness of the insulator 406a is made large, a distance from an interface between the adjacent insulator and the insulator 406a to the semiconductor 406b in which a channel is formed can be large. Since the productivity of the semiconductor device might be decreased, the insulator 406a has a region with a thickness of, for example, less than or equal to 200 nm, preferably less than or equal to 120 nm, and further preferably less than or equal to 80 nm.

A region with a silicon concentration measured by secondary ion mass spectrometry (SIMS) of higher than or equal to 1×10¹⁶ atoms/cm³ and lower than or equal to 1×10¹⁹ atoms/cm³, preferably higher than or equal to 1×10¹⁶ atoms/cm³ and lower than or equal to 5×10¹⁸ atoms/cm³, further preferably higher than or equal to 1×10¹⁶ atoms/cm³ and lower than or equal to 2×10¹⁸ atoms/cm³ is provided between the semiconductor 406b and the insulator 406a, for example. A region with a silicon concentration measured by SIMS of higher than or equal to 1×10¹⁶ atoms/cm³ and lower than or equal to 1×10¹⁹ atoms/cm³, preferably higher than or equal to 1×10¹⁶ atoms/cm³ and lower than or equal to 5×10¹⁸ atoms/cm³, further preferably higher than or equal to 1×10¹⁶ atoms/cm³ and lower than or equal to 2×10¹⁸ atoms/cm³ is provided between the semiconductor 406b and the insulator 406c.

The semiconductor 406b includes a region with a hydrogen concentration measured by SIMS of higher than or equal to 1×10¹⁶ atoms/cm³ and lower than or equal to 2×10²⁰ atoms/cm³, preferably higher than or equal to 1×10¹⁶ atoms/cm³ and lower than or equal to 5×10¹⁹ atoms/cm³, further preferably higher than or equal to 1×10¹⁶ atoms/cm³ and lower than or equal to 1×10¹⁹ atoms/cm³, or still further preferably higher than or equal to 1×10¹⁶ atoms/cm³ and lower than or equal to 5×10¹⁸ atoms/cm³. It is preferable to reduce the hydrogen concentration in the insulator 406a and the insulator 406c in order to reduce the hydrogen concentration in the semiconductor 406b. The insulator 406a and the insulator 406c each include a region with a hydrogen concentration measured by SIMS of higher than or equal to 1×10¹⁶ atoms/cm³ and lower than or equal to 2×10²⁰ atoms/cm³, preferably higher than or equal to 1×10¹⁶ atoms/cm³ and lower than or equal to 5×10¹⁹ atoms/cm³, further preferably higher than or equal to 1×10¹⁶ atoms/cm³ and lower than or equal to 1×10¹⁹ atoms/cm³, or still further preferably higher than or equal to 1×10¹⁶ atoms/cm³ and lower than or equal to 5×10¹⁸ atoms/cm³. The semiconductor 406b includes a region with a nitrogen concentration measured by SIMS of higher than or equal to 1×10¹⁵ atoms/cm³ and lower than or equal to 5×10¹⁹ atoms/cm³, preferably higher than or equal to 1×10¹⁵ atoms/cm³ and lower than or equal to 5×10¹⁸ atoms/cm³, further preferably higher than or equal to 1×10¹⁵ atoms/cm³ and lower than or equal to 1×10¹⁸ atoms/cm³, or still further preferably higher than or equal to 1×10¹⁵ atoms/cm³ and lower than or equal to 5×10¹⁷ atoms/cm³. It is preferable to reduce the nitrogen concentration in the insulator 406a and the insulator 406c in order to reduce the nitrogen concentration in the semiconductor 406b. The insulator 406a and the insulator 406c each include a region with a nitrogen concentration measured by SIMS of higher than or equal to 1×10¹⁵ atoms/cm³ and lower than or equal to 5×10¹⁹ atoms/cm³, preferably higher than or equal to 1×10¹⁵ atoms/cm³ and lower than or equal to 5×10¹⁸ atoms/cm³, further preferably higher than or equal to 1×10¹⁵ atoms/cm³ and lower than or equal to 1×10¹⁸ atoms/cm³, or still further preferably higher than or equal to 1×10¹⁵ atoms/cm³ and lower than or equal to 5×10¹⁷ atoms/cm³.

The above three-layer structure is an example. For example, a two-layer structure without the insulator 406a or the insulator 406c may be employed. Alternatively, a four-layer structure in which any one of the semiconductors described as examples of the insulator 406a, the semiconductor 406b, and the insulator 406c is provided under or over the insulator 406a or under or over the insulator 406c may be employed. An n-layer structure (n is an integer of 5 or more) in which one or more of the semiconductors described as examples of the insulator 406a, the semiconductor 406b, and the insulator 406c is/are provided at two or more of the following positions: over the insulator 406a, under the insulator 406a, over the insulator 406c, and under the insulator 406c.

### <Transistor 2>

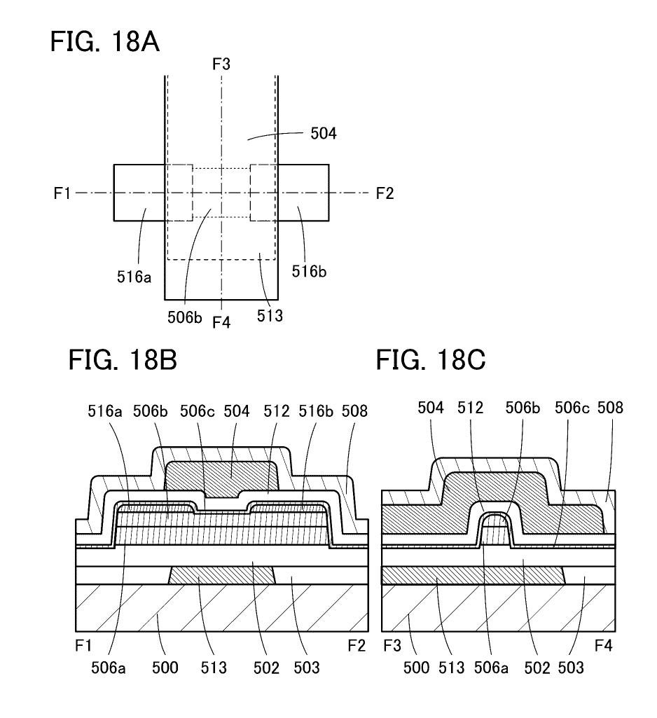

FIGS. 18A to 18C are a top view and cross-sectional views illustrating a transistor of one embodiment of the present invention. FIG. 18A is a top view, and FIGS. 18B and 18C are cross-sectional views taken along dashed-dotted lines F1-F2 and F3-F4 in FIG. 18A, respectively. Note that for simplification of the drawing, some components are not illustrated in the top view in FIG. 18A.

A transistor illustrated in FIGS. 18A to 18C includes a conductor 513 over a substrate 500; an insulator 503 that is over the substrate 500 and is level with the conductor 513; an insulator 502 over the conductor 513 and the insulator 503; an insulator 506a over the insulator 502; a semiconductor 506b over the insulator 506a; a conductor 516a and a conductor 516b which are arranged to be separated from each other while being in contact with the top surface of the semiconductor 506b; an insulator 506c over the insulator 502, the semiconductor 506b, the conductor 516a, and the conductor 516b; an insulator 512 over the insulator 506c; a conductor 504 over the insulator 512; and an insulator 508 over the conductor 504. Note that although the conductor 513 is part of the transistor in this non-limiting example, the conductor 513 may be a component independent of the transistor, for example. Furthermore, the transistor does not necessarily include the insulator 508. The transistor may include an insulator between the conductor 516a and the insulator 506c and/or between the conductor 516b and the insulator 506c. For the insulator, refer to the description of the insulator 410.

For the substrate 500, refer to the description of the substrate 400. For the conductor 513, refer to the description of the conductor 413. For the insulator 502, refer to the description of the insulator 402. For the insulator 506a, refer to the description of the insulator 406a. For the semiconductor 506b, refer to the description of the semiconductor 406b. For the conductor 516a, refer to the description of the conductor 416a. For the conductor 516b, refer to the description of the conductor 416b. For the insulator 506c, refer to the description of the insulator 406c. For the insulator 512, refer to the description of the insulator 412. For the conductor 504, refer to the description of the conductor 404. For the insulator 508, refer to the description of the insulator 408.

The insulator 503 may be formed to have a single-layer structure or a stacked-layer structure including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 503 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

As illustrated in FIG. 18C, the transistor has an s-channel structure. The electric field from the conductor 504 and the conductor 513 is less likely to be inhibited by the conductor 516a, the conductor 516b, and the like at the side surface of the semiconductor 506b.

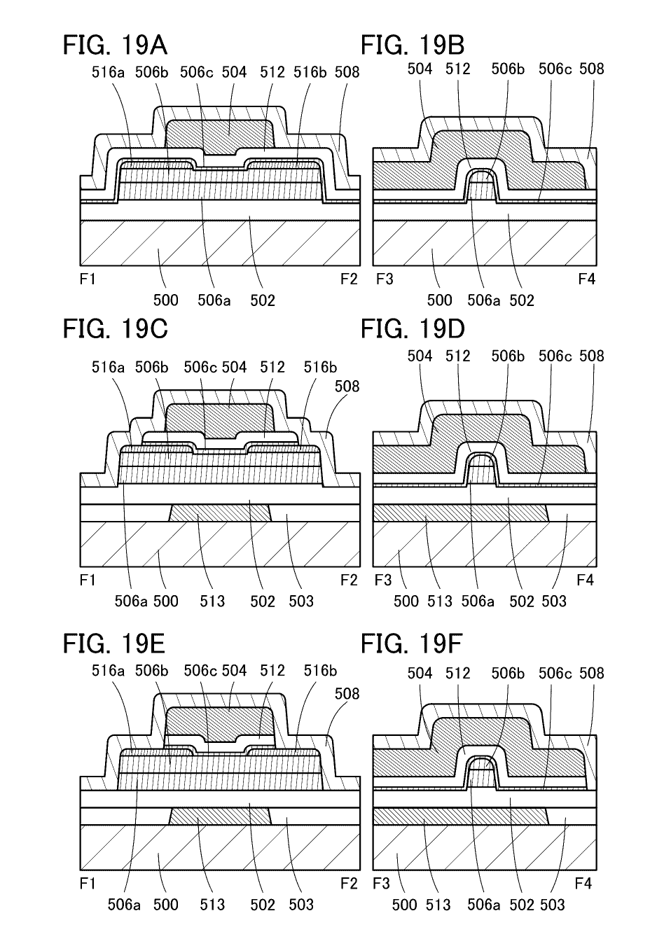

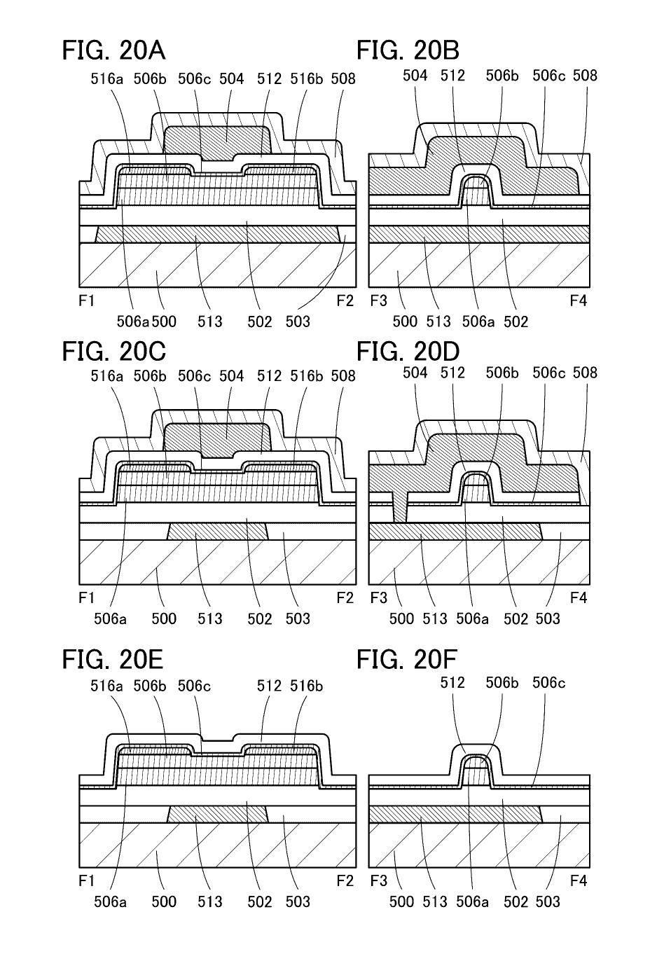

Note that the conductor 513 is not necessarily formed (see FIGS. 19A and 19B). A shape in which the insulator 512 and the insulator 506c protrude from the conductor 504 may be employed (see FIGS. 19C and 19D). A shape in which the insulator 512 and the insulator 506c do not protrude from the conductor 504 may be employed (see FIGS. 19E and 19F). In the F1-F2 cross section, the width of the conductor 513 may be larger than that of the semiconductor 506b (see FIGS. 20A and 20B). The conductor 513 may be in contact with the conductor 504 through an opening (see FIGS. 20C and 20D). The conductor 504 is not necessarily formed (see FIGS. 20E and 20F).

### <Transistor 3>

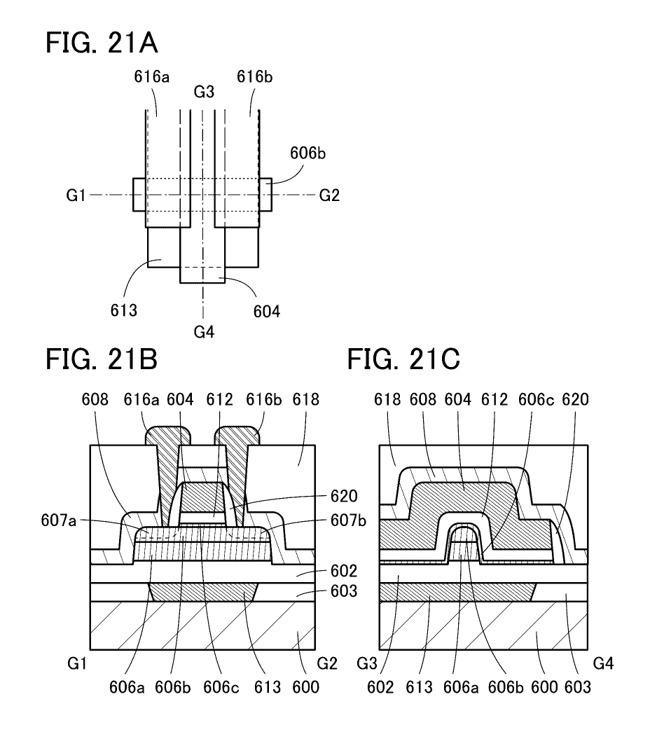

FIGS. 21A to 21C are a top view and cross-sectional views of a transistor of one embodiment of the present invention. FIG. 21A is the top view. FIG. 21B and FIG. 21C are the cross-sectional views taken along the dashed-dotted line G1-G2 and the dashed-dotted line G3-G4, respectively, in FIG. 21A. Note that for simplification of the drawing, some components are not illustrated in the top view in FIG. 21A.

The transistor shown in FIGS. 21A to 21C includes a conductor 613 over a substrate 600; an insulator 603 that is over the substrate 600 and is level with the conductor 613; an insulator 602 over the conductor 613 and the insulator 603; an insulator 606a over the insulator 602; a semiconductor 606b over the insulator 606a; an insulator 606c over the semiconductor 606b; an insulator 612 over the insulator 606c; a conductor 604 over the insulator 612; an insulator 620 including a region which is in contact with a side surface of the conductor 604 and a top surface of the semiconductor 606b; and an insulator 608 over the insulator 602, the semiconductor 606b, the conductor 604, and the insulator 620. Although the conductor 613 is part of the transistor, a transistor structure of one embodiment of the present invention is not limited thereto. For example, the conductor 613 may be a component independent of the transistor. The transistor does not necessarily include the insulator 608.

The semiconductor 606b includes a region 607a and a region 607b. A region overlapping with the conductor 604 in the semiconductor 606b is provided between the region 607a and the region 607b. The region 607a and the region 607b each include a region with a lower resistance than a region in the semiconductor 606b except the region 607a and the region 607b. The region 607a and the region 607b have a function as the source region and the drain region of the transistor.

An insulator 618 may be provided over the insulator 608. The insulator 618 and the insulator 608 include two opening portions. The two opening portions reach the region 607a and the region 607b. The conductor 616a and the conductor 616b fill the two opening portions. At this time, the insulator 620 has a function of suppressing electrical connection of the conductors 616a and 616b to the conductor 604.

For the substrate 600, refer to the description of the substrate 400. For the conductor 613, refer to the description of the conductor 413. For the insulator 602, refer to the description of the insulator 402. For the insulator 603, refer to the description of the insulator 503. For the insulator 606a, refer to the description of the insulator 406a. For the semiconductor 606b, refer to the description of the semiconductor 406b. For the conductor 616a, refer to the description of the conductor 416a. For the conductor 616b, refer to the description of the conductor 416b. For the insulator 606c, refer to the description of the insulator 406c. For the insulator 612, refer to the description of the insulator 412. For the conductor 604, refer to the description of the conductor 404. For the insulator 608, refer to the description of the insulator 408.

The insulator 620 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 620 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulator 618 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 618 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

As illustrated in FIG. 21C, the transistor has an s-channel structure. The electric field from the conductor 604 and the conductor 613 is less likely to be inhibited by the conductor 616a, the conductor 616b, and the like at the side surface of the semiconductor 606b.

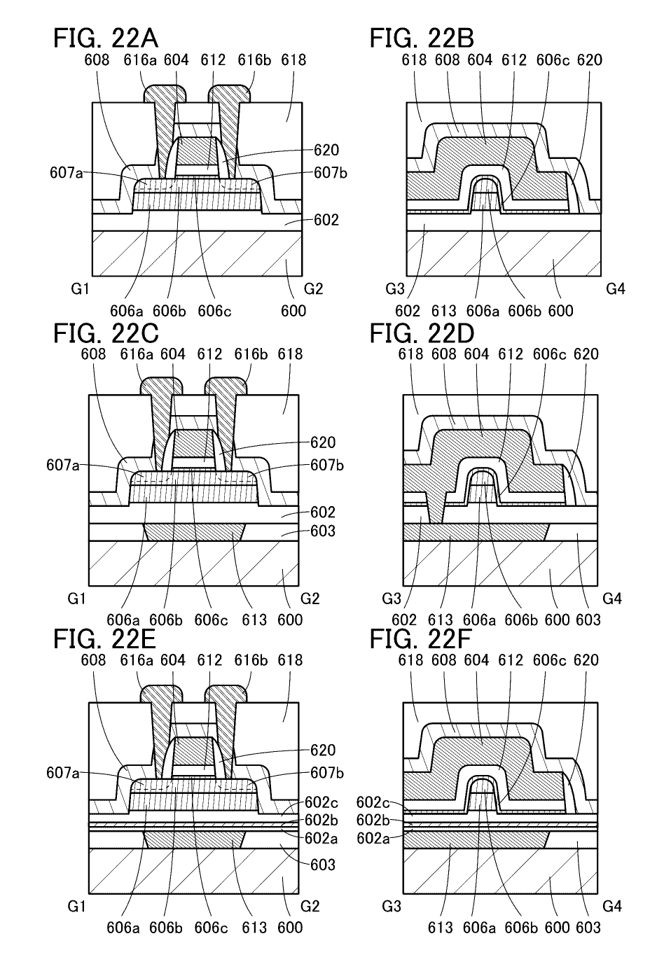

Note that the conductor 613 is not necessarily formed (see FIGS. 22A and 22B). The conductor 613 may be in contact with the conductor 604 through an opening portion (see FIGS. 22C and 22D). Instead of the insulator 602, a stacked-layer film in which an insulator 602a, an insulator 602b, and an insulator 602c are stacked in the order presented may be used (see FIGS. 22E and 22F).

The insulators 602a, 602b, and 602c may each be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. For example, the insulator 602a and the insulator 602c are formed using silicon oxide or silicon oxynitride, and the insulator 602b is formed using aluminum oxide, magnesium oxide, silicon nitride oxide, silicon nitride, gallium oxide, germanium oxide, yttrium oxide, zirconium oxide, lanthanum oxide, neodymium oxide, hafnium oxide, or tantalum oxide. The insulator 602b preferably has a carrier trap. In that case, when a potential is applied to the conductor 613, an electron or the like is trapped by the carrier trap in the insulator 602b, so that the threshold voltage of the transistor can be shifted. For example, the threshold voltage of the transistor is shifted in the positive direction, whereby the transistor can have normally-off characteristics.

This application is based on Japanese Patent Application serial no. 2015-168610 filed with Japan Patent Office on Aug. 28, 2015 and Japanese Patent Application serial no. 2015-168607 filed with Japan Patent Office on Aug. 28, 2015, the entire contents of which are hereby incorporated by reference.

What is claimed is:

1. A film forming apparatus comprising:
a target holder;
a substrate holder;
a first power source; and
a second power source,
wherein the target holder is electrically connected to the first power source,
wherein the substrate holder is electrically connected to the second power source, and
wherein the second power source is configured to apply a potential that is higher than a ground potential.

2. The film forming apparatus according to claim 1, wherein the potential is higher than a potential of plasma generated during film formation.

3. The film forming apparatus according to claim 1, wherein a maximum magnetic flux density in a direction perpendicular to a front surface of the target holder is more than or equal to 50 G and less than or equal to 150 G at a plane that is 30 mm away in a perpendicular direction from the front surface of the target holder.

4. A film forming apparatus comprising:
a target holder;
a substrate holder;
a first inlet; and
a second inlet,
wherein the first inlet is positioned closer to the target holder than to the substrate holder,
wherein the second inlet is positioned closer to the substrate holder than to the target holder,
wherein the first inlet is configured to introduce a first gas, and
wherein the second inlet is configured to introduce a second gas.

5. The film forming apparatus according to claim 4, wherein, during film formation, a concentration of the first gas near the target holder is high and a concentration of the second gas near the substrate holder is high.

6. The film forming apparatus according to claim 4, wherein a maximum magnetic flux density in a direction perpendicular to a front surface of the target holder is more than or equal to 50 G and less than or equal to 150 G at a plane that is 30 mm away in a perpendicular direction from the front surface of the target holder.

7. A film forming apparatus comprising:
a first target holder;
a second target holder;
a substrate holder;
a first power source; and
a second power source,
wherein the first target holder and the second target holder are electrically connected to the first power source,
wherein the substrate holder is electrically connected to the second power source, and
wherein the second power source is configured to apply a potential that is higher than a ground potential.

8. The film forming apparatus according to claim 7, wherein the potential is higher than a potential of plasma generated during film formation.

9. The film forming apparatus according to claim 7, wherein a maximum magnetic flux density in a direction perpendicular to a front surface of the first target holder is more than or equal to 50 G and less than or equal to 150 G at a plane that is 30 mm away in a perpendicular direction from the front surface of the first target holder.

10. The film forming apparatus according to claim 7, wherein a maximum magnetic flux density in a direction perpendicular to a front surface of the second target holder is more than or equal to 50 G and less than or equal to 150 G at a plane that is 30 mm away in a perpendicular direction from the front surface of the second target holder.

11. A film forming apparatus comprising:
a first target holder;
a second target holder;
a substrate holder;
a first inlet; and
a second inlet,
wherein the first inlet is positioned closer to the first target holder and the second target holder than to the substrate holder,
wherein the second inlet is positioned closer to the substrate holder than to the first target holder and the second target holder,
wherein the first inlet is configured to introduce a first gas, and
wherein the second inlet is configured to introduce a second gas.

12. The film forming apparatus according to claim 11, wherein, during film formation, a concentration of the first gas near the first target holder and the second target holder is high and a concentration of the second gas near the substrate holder is high.

13. The film forming apparatus according to claim 11, wherein a maximum magnetic flux density in a direction perpendicular to a front surface of the first target holder is more than or equal to 50 G and less than or equal to 150 G at a plane that is 30 mm away in a perpendicular direction from the front surface of the first target holder.

14. The film forming apparatus according to claim 11, wherein a maximum magnetic flux density in a direction perpendicular to a front surface of the second target holder is more than or equal to 50 G and less than or equal to 150 G at a plane that is 30 mm away in a perpendicular direction from the front surface of the second target holder.
